(19) United States
(12) Patent Application Publication
(10) Pub. No.: US 2014/0377889 A1
(43) Pub. Date: Dec. 25, 2014

(54) SEMICONDUCTOR DEVICE MANUFACTURING METHOD

(71) Applicant: Renesas Electronics Corporation, Kawasaki-shi (JP)

(72) Inventors: Hiraku Chakihara, Kanagawa (JP); Akihiro Nakae, Kanagawa (JP); Masaaki Shinohara, Kanagawa (JP); Yasushi Ishii, Kanagawa (JP)

(73) Assignee: RENESAS ELECTRONICS CORPORATION

(21) Appl. No.: 14/304,951

(22) Filed: Jun. 15, 2014

(30) Foreign Application Priority Data
Jun. 25, 2013 (JP) 2013-133074

(51) Int. Cl. H01L 21/66; H01L 21/033

(52) U.S. Cl. CPC H01L 22/12; H01L 21/0337
USPC 438/14

(57) ABSTRACT

A semiconductor device manufacturing method which eliminates the possibility that when a film is processed several times, a thin photoresist film is made over a pattern used as an alignment mark, etc. and the pattern is exposed from the photoresist film and removed in a processing step, in order to improve the reliability of a semiconductor device. Patterns used as alignment marks, etc. are linear trenches as openings in a conductive film made over a semiconductor substrate, thereby preventing the photoresist film over the conductive film from flowing toward the openings in the conductive film.

### CROSS-REFERENCE TO RELATED APPLICATIONS

The disclosure of Japanese Patent Application No. 2013-133074 filed on Jun. 25, 2013 including the specification, drawings and abstract is incorporated herein by reference in its entirety.

### BACKGROUND

The present invention relates to semiconductor device manufacturing technology and more particularly to a technique for manufacturing a semiconductor device in which in lithography or a similar process, a mark as a pattern formed over a substrate is detected and the position of the mark is checked.

It is known that the photolithographic technique or etching method is used to partially remove a film formed over a semiconductor substrate and process it in a semiconductor device manufacturing process. When using the photolithographic technique, for example, after a photoresist film is coated over the semiconductor substrate, the photoresist film is partially exposed through a photo mask using an exposure apparatus to transfer a pattern. Then, either irradiated film portions or unirradiated film portions are selectively removed and the resultant photoresist film is used as a mask to etch a film over the semiconductor substrate partially to perform patterning.

In the above process, in order to determine the position of the photo mask with respect to the semiconductor substrate in the exposure apparatus, a positioning method may be employed in which an alignment mark for positioning, as a pattern over the semiconductor substrate, is observed.

One method for checking whether or not there is a misalignment of the pattern formed by patterning the film over the semiconductor substrate, with respect to the underlying semiconductor substrate is to inspect a plurality of inspection marks made during each patterning process.

In recent years, as an element used as a nonvolatile memory cell, a MONOS (Metal Oxide Nitride Oxide Semiconductor) nonvolatile memory cell (which hereinafter may be called a MONOS memory) which uses a nitride film for a charge storage layer has been attracting attention. As a MONOS nonvolatile memory cell, in addition to a memory cell with a single transistor structure, a split gate memory cell which has two transistor structures with select gate electrodes and memory gate electrodes has been proposed.

The select gate electrode and memory gate electrode which include the split gate MONOS memory arranged adjacent to each other over the semiconductor substrate are electrically isolated by an insulating film, including a charge storage layer, between them. In operation of the MONOS memory, charge is taken into or out of the charge storage layer to store or erase information.

PCT International Publication No. WO 2010/082389 describes that when a MONOS memory and a transistor are formed over a semiconductor substrate, a select gate electrode is formed for the MONOS memory by processing a semiconductor film partially, and then a gate electrode is formed for the transistor by processing another portion of the semiconductor film.

### SUMMARY

When a semiconductor substrate is diced into individual semiconductor chips, for example, a positioning alignment mark or inspection mark as mentioned above may be made in a scribe region in which cutting is done. In that case, a linear pattern may be formed or left in a relatively large region and this pattern may be used as a mark to position a photo mask. However, if such a linear pattern is sparsely formed on a relatively large plane over the semiconductor substrate, when a photoresist film is coated over the semiconductor substrate in a later step, the photoresist film immediately above the mark pattern would be thinner than in the region in which gate electrode patterns and other patterns are densely formed, and the photoresist film would accumulate beside the linear mark pattern, forming a thick photoresist film area.

If etching is performed in this condition, since the photoresist film immediately above the mark pattern is thin, that photoresist film portion might be removed by etching and the pattern exposed from the photoresist film might be etched. When the pattern used as a mark is inspected, the corner in the boundary between the upper surface and sidewall of the pattern is detected to recognize the shape of the pattern. Therefore, if the pattern gets chipped during the above etching step, it would be impossible to detect the mark accurately. This would pose the problem that photo mask positioning accuracy declines and the problem that it is difficult to inspect the position of the pattern formed over the substrate. This would lead to deterioration in the reliability of the semiconductor device.

The above and further objects and novel features of the invention will more fully appear from the following detailed description in this specification and the accompanying drawings.

A major aspect of the present invention which will be disclosed herein is briefly outlined below.

According to one aspect of the present invention, there is provided a semiconductor device manufacturing method in which a film made in a first region and a second region over a semiconductor substrate is processed to form a trench in the first region and the trench serves as a pattern used as an alignment mark or the like and in a later step, the film in the second region is processed by an etching process using the photolithographic technique.

According to the present invention, the reliability of the semiconductor device can be improved.

### BRIEF DESCRIPTION OF THE DRAWINGS

FIG. 1 is a plan view showing a semiconductor device manufacturing method according to an embodiment of the present invention;

FIG. 2 is a sectional view showing the semiconductor device manufacturing method according to the embodiment;

FIG. 3 is a sectional view showing a step subsequent to the step shown in FIG. 2 in the semiconductor device manufacturing method;

FIG. 4 is a sectional view showing a step subsequent to the step shown in FIG. 3 in the semiconductor device manufacturing method;

FIG. 5 is a plan view showing a step subsequent to the step shown in FIG. 4 in the semiconductor device manufacturing method;

FIG. 6 is a sectional view showing a step subsequent to the step shown in FIG. 4 in the semiconductor device manufacturing method;

FIG. 7 is a sectional view showing a step subsequent to the step shown in FIG. 6 in the semiconductor device manufacturing method;

FIG. 8 is a sectional view showing a step subsequent to the step shown in FIG. 7 in the semiconductor device manufacturing method;

FIG. 9 is a sectional view showing a step subsequent to the step shown in FIG. 8 in the semiconductor device manufacturing method;

FIG. 10 is a sectional view showing a step subsequent to the step shown in FIG. 9 in the semiconductor device manufacturing method;

FIG. 11 is a sectional view showing a step subsequent to the step shown in FIG. 10 in the semiconductor device manufacturing method;

FIG. 12 is a sectional view showing a step subsequent to the step shown in FIG. 11 in the semiconductor device manufacturing method;

FIG. 13 is a plan view showing a step subsequent to the step shown in FIG. 11 in the semiconductor device manufacturing method;

FIG. 14 is a sectional view showing a step subsequent to the step shown in FIG. 12 in the semiconductor device manufacturing method;

FIG. 15 is a sectional view showing a step subsequent to the step shown in FIG. 14 in the semiconductor device manufacturing method;

FIG. 16 is a sectional view showing a step subsequent to the step shown in FIG. 15 in the semiconductor device manufacturing method;

FIG. 17 is a sectional view showing a step subsequent to the step shown in FIG. 16 in the semiconductor device manufacturing method;

FIG. 18 is a sectional view showing a step subsequent to the step shown in FIG. 17 in the semiconductor device manufacturing method;

FIG. 19 is a sectional view showing a step subsequent to the step shown in FIG. 18 in the semiconductor device manufacturing method;

FIG. 20 is a sectional view showing a step subsequent to the step shown in FIG. 19 in the semiconductor device manufacturing method;

FIG. 21 is a sectional view showing a step subsequent to the step shown in FIG. 20 in the semiconductor device manufacturing method;

FIG. 22 is a plan view showing a semiconductor device manufacturing method according to a comparative example;

FIG. 23 is a sectional view showing a step in the semiconductor device manufacturing method according to the comparative example;

FIG. 24 is a sectional view showing a step subsequent to the step shown in FIG. 23 in the semiconductor device manufacturing method; and

FIG. 25 is a sectional view showing a step subsequent to the step shown in FIG. 24 in the semiconductor device manufacturing method.

### DETAILED DESCRIPTION

Next, the preferred embodiment of the present invention will be described referring to the accompanying drawings. In all the drawings that illustrate the preferred embodiment, elements with like functions are designated by like reference numerals and repeated descriptions thereof are omitted. Basically, descriptions of like or similar elements of the embodiment will not be repeated unless necessary.

In the drawings used to illustrate the embodiment, hatching may be used even in a plan view for easy understanding.

This embodiment concerns a technique that a trench is used as a mark for photo mask positioning or pattern position check to prevent the photoresist film over the mark from becoming thin, thereby enhancing the detection accuracy of the mark.

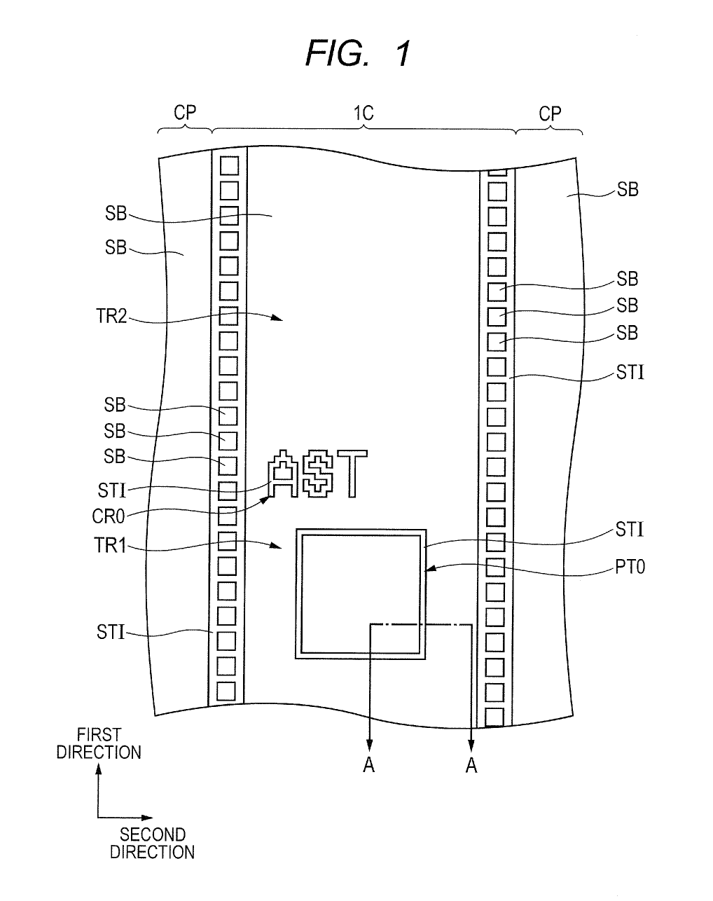

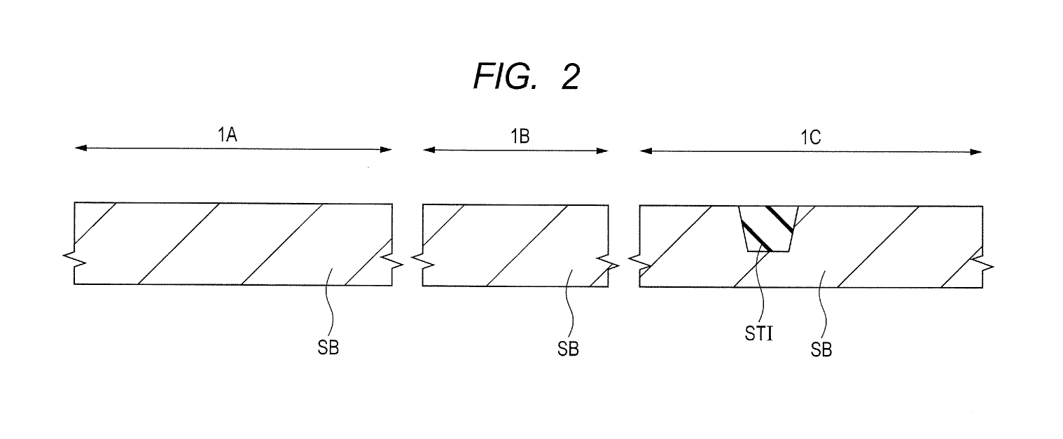

First, the method for manufacturing a semiconductor device with a nonvolatile memory cell according to this embodiment will be described step by step sequentially referring to FIGS. 1 to 21. FIGS. 2 to 4, FIGS. 6 to 12, and FIGS. 14 to 21 are sectional views of steps of the semiconductor device manufacturing method according to this embodiment, each showing a split gate MONOS memory, a MISFET (Metal Insulator Semiconductor Field Effect Transistor) in a peripheral circuit region, and a scribe region for the formation of an inspection mark from left to right. Specifically, in the sectional views of FIGS. 2 to 4, FIGS. 6 to 12, and FIGS. 14 to 21, a memory region 1A, a peripheral circuit region 1B, and a scribe region 1C are shown from left.

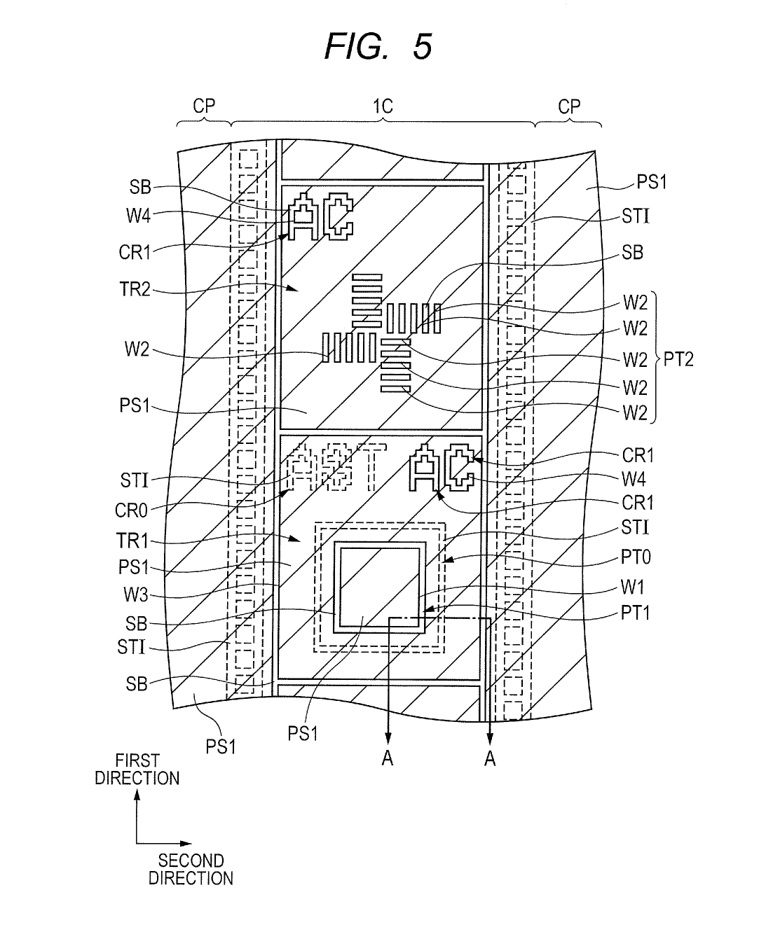

FIGS. 1, 5, and 13 are plan views of the semiconductor device according to this embodiment which is under the manufacturing process. In the plan views of FIG. 5 and subsequent figures, the pattern of the semiconductor film surrounding the inspection mark is indicated by hatching. In other words, the semiconductor film in other regions than the region indicated by hatching is removed. In the present invention, in some cases the pattern of the alignment mark used for positioning in the lithographic process and the pattern used to check the gate electrode pattern formed over the substrate will be collectively called inspection patterns or inspection marks.

FIGS. 2 to 4, FIGS. 6 to 12, and FIGS. 14 to 21 each show a cross section of the memory region 1A in a step of manufacturing a pair of memory cells of a nonvolatile memory device and a cross section of the peripheral circuit region 1B in a step of manufacturing an n-type low-voltage MISFET of a peripheral circuit. Hereinafter the n-type MISFET will be simply called nMIS.

In the sectional views given below, only a very small number of elements are shown for easy understanding. Actually, however, in the memory region 1A, a plurality of memory cells as mentioned above is densely disposed and in the peripheral circuit region 1B, not only the plural low-voltage nMIS but also a plurality of low-voltage pMIS and high-voltage nMIS or high-voltage pMIS are densely disposed.

First, as shown in FIGS. 1 and 2, a trench-type element isolation region STI and an active region surrounded by the element isolation region STI are formed on the main surface of a semiconductor substrate SB as a semiconductor thin plate with a virtually circular planar shape, called a wafer. More specifically, after an isolation trench is formed in a given place on the main surface of the semiconductor substrate SB, an insulating film such as a silicon oxide film is deposited over the main surface of the semiconductor substrate SB and the insulating film is embedded in the isolation trench by polishing the insulating film, for example, by the CMP (Chemical Mechanical Polishing) method so that the insulating film is left only in the isolation trench. The element isolation region STI which has, for example, an STI (Shallow Trench Isolation) structure is thus formed.

Although it is assumed here that the element isolation region STI formed on the main surface of the semiconductor substrate SB has an STI structure, the element isolation region STI is not limited thereto. For example, it may have a LOCOS (Local Oxidization of Silicon) structure.

As shown in FIG. 1, element isolation regions STI are also formed at both ends of the scribe region 1C in the direction perpendicular to the direction in which the scribe region 1C extends. The scribe regions 1C are located so as to surround the regions which turn into semiconductor chips in a later step (hereinafter called chip regions CP). FIG. 1 shows a scribe region 10 extending along one of the four sides of a chip region CP which is rectangular in a plan view.

A plurality of chip regions CP is arranged in a first direction along the main surface of the semiconductor substrate SB and in the second direction perpendicular to the first direction. In other words, the chip regions CP are arranged in a matrix pattern. Scribe regions 10, extending in the first or second direction along the main surface of the semiconductor substrate SB, are arranged in a grid pattern. Therefore, a scribe region 10 extending in the first direction is arranged between neighboring chip regions CP in the second direction and a scribe region 10 (not shown) extending in the second direction is arranged between neighboring chip regions in the first direction.

Here an element isolation region STI is formed within a scribe region 10 adjacently to a chip region CP. The element isolation region STI extends at an end in the scribe region 10 along the scribe region 10. Also, in the element isolation region STI in the scribe region 10, a plurality of active regions is arranged and spaced at regular intervals along the direction in which the element isolation region extends. This arrangement is intended to prevent the upper surface of the element isolation region STI from becoming dented by dishing in the polishing step to make the element isolation region STI.

A cross section of the scribe region 10, taken along the line A-A of FIG. 1, is shown in FIG. 2. The memory region 1A and peripheral circuit region 1B shown in FIG. 2 are portions of the chip region CP (see FIG. 1).

The scribe region 1C includes a plurality of regions in which a mark used for positioning or inspection of the pattern position in the lithographic process is formed. Hereinafter such regions will be simply called mark regions. The mark regions are arranged side by side in the direction in which the scribe region 1C extends. Mark regions TR1 and TR2 are shown in FIG. 1. Each of the mark regions is arranged between the element isolation regions STI at both ends of the scribe region 1C.

In the above step, the element isolation regions STI are formed at the ends of the scribe region 1C and also an annular pattern PT0, made of an element isolation region STI and rectangular in a plan view, is formed in the mark region TR1. Specifically, the pattern PT0 which is made of an element isolation region STI embedded in a trench in the main surface of the semiconductor substrate SB has a rectangular frame-like shape in a plan view. At the same time, a character pattern CRO made of an element isolation region STI is formed on the surface of the semiconductor substrate SB in the mark region TR1. The character pattern CRO is, for example, a character string “AST” as shown in FIG. 1.

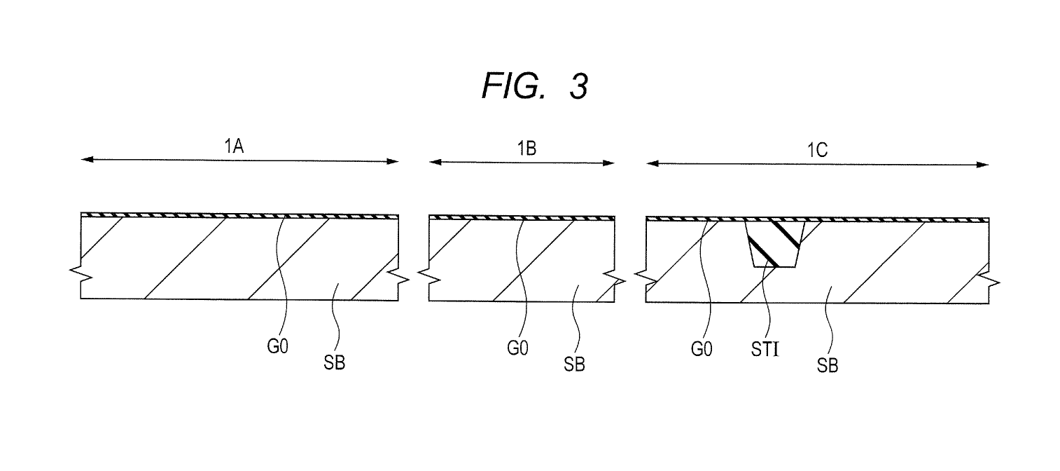

Next, as shown in FIG. 3, a p-well (not shown) is formed by selectively implanting p-type impurity ions into the semiconductor substrate SB in the memory region 1A and similarly a p-well (not shown) is formed by selectively implanting p-type impurity ions into the semiconductor substrate SB in the peripheral circuit region 1B.

Next, p-type impurity ions, for example, B (boron) ions, are selectively implanted into the semiconductor substrate SB in the memory region 1A. Consequently a p-type semiconductor region (not shown) for the MONOS memory channel to be formed in a later step is formed in the semiconductor substrate SB in the memory region 1A. Similarly, a semiconductor region (not shown) for channel formation is formed by implanting given impurity ions into the semiconductor substrate SB in the peripheral circuit region 1B.

Next, an insulating film G0, for example, of silicon oxide with a thickness of 1 to 5 nm is formed in each region of the main surface of the semiconductor substrate SB by oxidation of the semiconductor substrate SB.

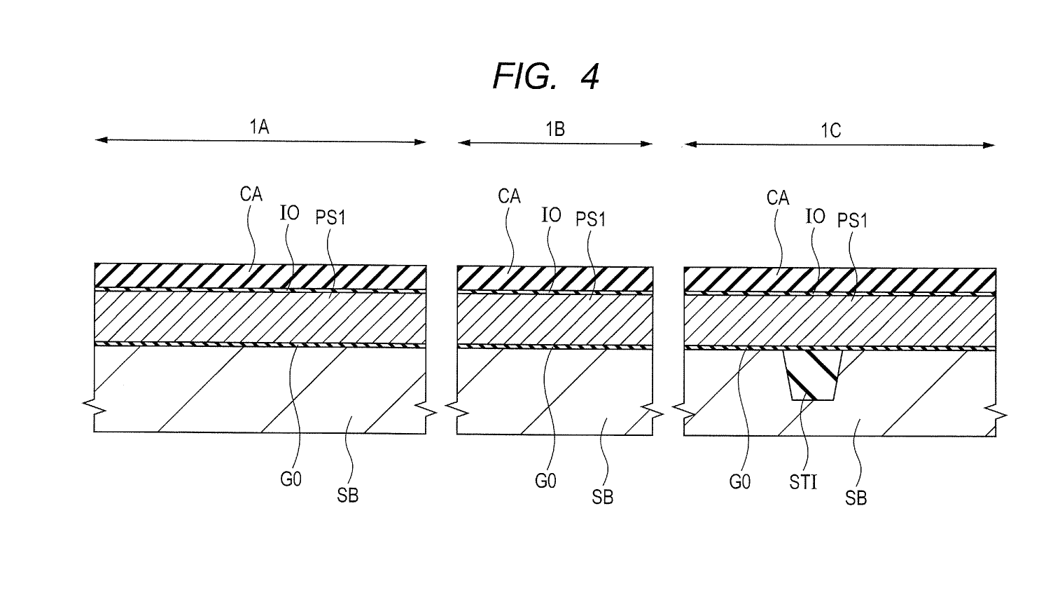

Next, as shown in FIG. 4, a conductive film PS1, for example, of amorphous silicon is deposited over the main surface of the semiconductor substrate SB by the CVD (Chemical Vapor Deposition) method and then n-type impurities are doped into the conductive film PS1 of the memory region 1A and peripheral circuit region 1B by the ion implanting method. The thickness of the conductive film PS1 is, for example, about 140 nm.

Next, insulating films IO and CA are formed over the conductive film PS1 sequentially by the CVD method or a similar method. The insulating film IO between the conductive film PS1 and insulating film CA is, for example, a silicon oxide film. The insulating film CA is made of silicon nitride, silicon oxide, silicon oxide containing nitrogen, or silicon carbide and its thickness is, for example, 50 nm. Consequently the element isolation region STI in the scribe region 1C shown in FIG. 4, namely the upper surface of the pattern PT0, is covered by the conductive film PS1 and insulating films IO and CA.

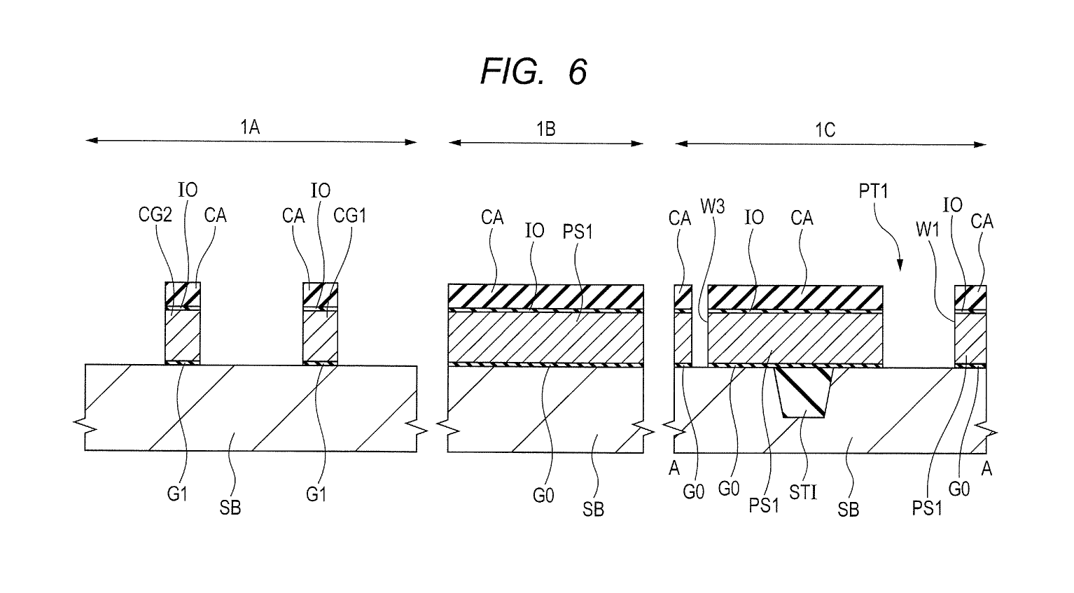

Next, as shown in FIGS. 5 and 6, patterning is done on the insulating films CA and IO, conductive film PS1 and insulating film G0 in the memory region 1A and scribe region 1C sequentially by the lithographic technique and dry etching technique. Consequently, as shown in FIG. 6, select gate electrodes CG1 and CG2 made of the conductive film PS1 and a gate insulating film G1 made of the insulating film G0 are formed in the memory region 1A. In other words, the select gate electrodes CG1 and CG2 are formed over the semiconductor substrate SB through the gate insulating film G1.

The gate length of the select gate electrodes CG1 and CG2 in the memory region 1A is, for example, about 100 nm. Since this etching step is carried out with the conductive film PS1 in the peripheral circuit region 1B covered by photoresist film (not shown), the conductive film PS1 in the peripheral circuit region 1B remains unprocessed.

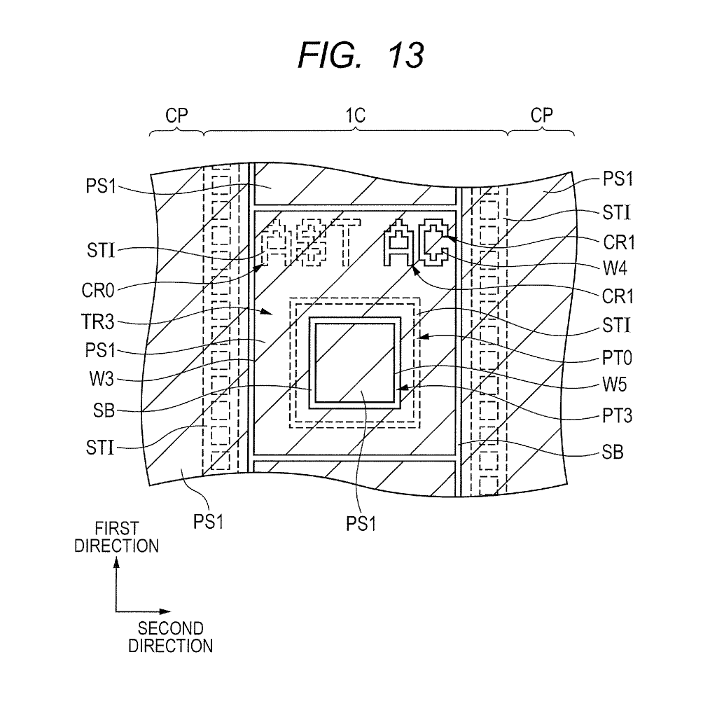

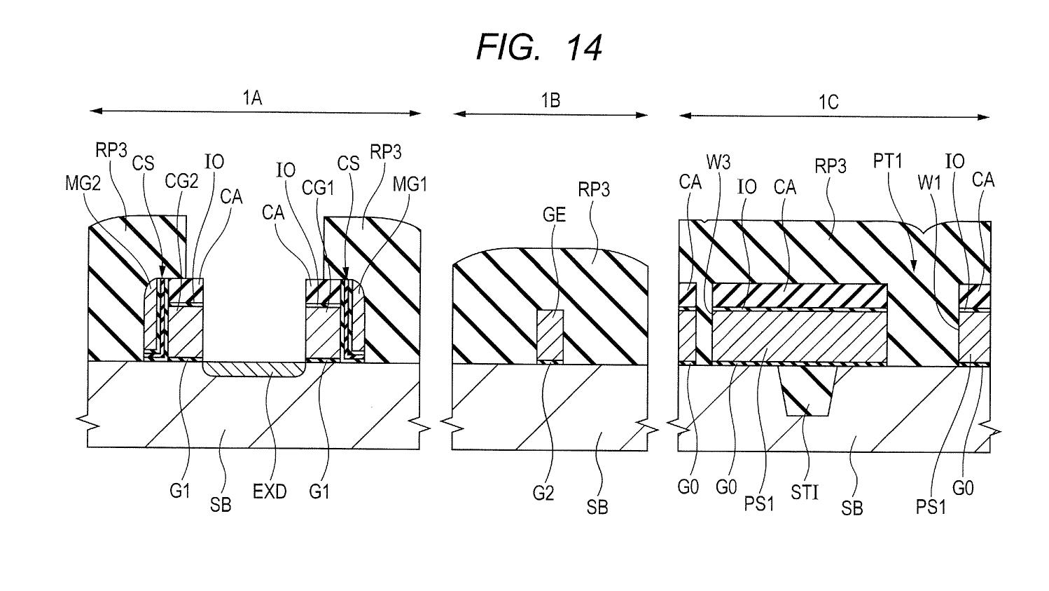

In FIG. 5, the insulating films IO and CA shown in FIG. 6 are omitted and the same is true for FIGS. 13 and 14 to which reference will be made later. In a plan view, the insulating films IO and CA have almost the same pattern as the conductive film PS1 just below them. The boundary between the upper surface of the semiconductor substrate SB and the upper surface of the element isolation region STI which is covered by the conductive film PS1 is indicated by broken lines. The hatching indicates the conductive film PS1 over the semiconductor substrate SB. In FIG. 5, the region not marked with hatching is recessed with respect to the conductive film PS1. A cross section of the scribe region 10 taken along the line A-A of FIG. 5 is shown in FIG. 6.

In FIG. 5, the element isolation regions STI at both ends of the scribe region 10, the character pattern CRO made of an element isolation region STI representing the character string “AST” and the annular pattern PT0 made of an element isolation region STI are indicated by broken lines.

Next, partial removal of the conductive film PS1 in the memory region 1A and scribe region 1C will be described. In this embodiment, a capacitive element formed by depositing a conductive film, insulating film and conductive film sequentially, for example, a PIP (Polysilicon Insulator Polysilicon) capacitive element may be formed over the semiconductor substrate SB. In that case, the conductive film PS1 is processed and left in the region (not shown) in which the capacitive element is formed, by the etching step described referring to FIGS. 5 and 6. The patterned conductive film PS1 in the region in which the capacitive element is formed functions as the lower electrode of the capacitive element.

In the scribe region 1C, a plurality of trenches, or openings, are made by partially removing the insulating films CA and IO, conductive film PS1 and insulating film G0 by the above etching step. A pattern PT1, made of a trench W as an opening in the insulating films CA and IO, conductive film PS1 and insulating film G0, is a pattern intended to inspect the positional relation with the pattern PT0.

The pattern PT1 has, for example, a rectangular frame-like shape in a plan view. Specifically, the conductive film PS1 is arranged inside and outside the pattern PT1 made of the trench W1 with four sides extending in the first and second directions in a plan view. The pattern PT1 is arranged inside the annular pattern PT0 in a plan view.

As shown in FIG. 5, a trench W3 is formed in the scribe region 1C as a boundary which separates mark regions TR1 and TR2 for the formation of inspection marks used in the above inspection, from the other regions. The mark regions TR1 and TR2 are both rectangular in a plan view. The trench W3 is arranged between the mark region TR1 or TR2 and the element isolation region STI at each end of the scribe region 1C. The trench W3 is also arranged between the mark regions TR1 and TR2. In short, the mark regions TR1 and TR2 are each surrounded and defined by the trench W3 and located between the element isolation regions STI at both ends in the scribe region 1C.

The pattern PT1 is formed in the mark region TR1. The mark regions TR1 and TR2 are arranged side by side in the direction in which the scribe region 1C extends and in the same direction, mark regions other than the mark regions TR1 and TR2 or TEG (Test Elemental Group) formation regions are arranged side by side.

A pattern PT2 as an alignment mark used to position a photo mask with respect to the semiconductor substrate SB in the exposure step using the lithographic technique is formed in the mark region TR2, adjacent to the mark region TR1 with the trench W3 between the mark regions. Like the trench W1, the pattern PT2 is formed in the same step as the pattern PT1 and made of a plurality of trenches W2 extending in a given direction. Although a sectional view of the region including the trenches W2 is given here, the sectional structure of each of the trenches W2 perpendicular to its extending direction is similar to that of the trench W1 shown in FIG. 6.

The pattern PT2 shown in FIG. 5 has trenches W2 extending, for example, in the first direction arranged side by side in the second direction in the mark region TR2. Also, the pattern PT2 has trenches W2 extending, for example, in the second direction arranged side by side in the first direction in the mark region TR2. In this embodiment, the mark region TR2 includes trenches W2 extending in both the first and second directions. Alternatively, however, the pattern PT2 in the mark region TR2 may have trenches extending in either the first direction or the second direction and not have trenches extending in another direction.

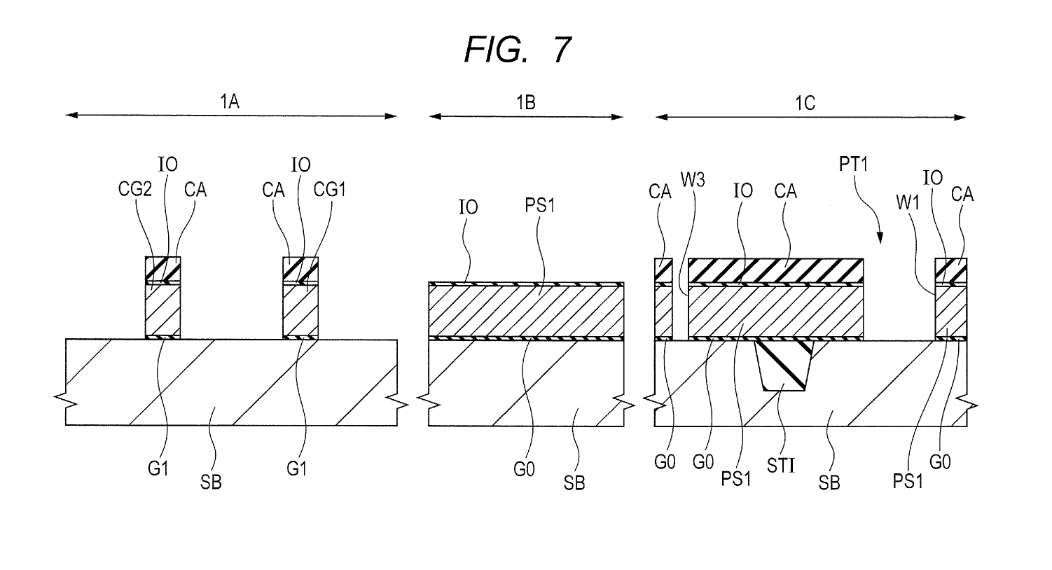

In the lithographic process which will be described later referring to FIGS. 7, 9, 11, 14 to 16, and 18, the position and orientation of the pattern PT2 are detected by observing, through the exposure apparatus, the pattern PT2 which has a plurality of linear trenches W2 arranged perpendicularly to the direction in which they extend as mentioned above, in order to determine the position of the photo mask with respect to the semiconductor substrate SB.

As mentioned above, the pattern PT1 in the mark region TR1 is a mark for inspection which is used to check if there is misalignment between patterns formed in the chip region CP, by observing its positional relation with a mark as a pattern which is formed in a later step. Also, as mentioned above, the pattern PT2 in the mark region TR2 is used to determine the position of the photo mask in a later step in which the photolithographic technique is employed.

When the pattern PT1 (PT2) is observed (inspected), the trench W1 (trenches W2) of the pattern is recognized by detecting the corner in the boundary between an inner sidewall of the trench W1 (trenches W2) and the laminated film including the conductive film PS1 having the sidewall. The corner is the corner of an edge of the upper surface of the laminated film including the conductive film PS1 and insulating films IO and CA. In the step of inspecting the patterns PT1 and PT2, a method in which the mark is observed using a microscope or a method in which the mark is detected by irradiation with infrared rays or laser light is adopted. Similarly the position of the pattern PT0 covered by the conductive film PS1 can be recognized by detecting such a corner.

Here, in order to detect, for example, the trenches W2 accurately using the inspection optical instrument built in the exposure apparatus or the like, it is important that the corner just above the sidewall of each trench W2 is virtually square. If the corner is chipped and partially missing or gently curved or rounded, it will be difficult to detect the position of the trench W2 accurately. Likewise, in order to detect the trench W1 to check the position of a formed pattern, it is important that the corner just above the sidewall of the trench W1 is virtually square.

In the plan view of FIG. 5, the corner exists in the boundary between the trench W1 (trenches W2) and the conductive film PS1. The pattern PT1, made of the trench W1, has a rectangular annular shape in the plan view. Specifically the trench W1 is a recess between the annular corner of the edge of a conductive film PS1 left in the form of an island and the annular corner of the edge of another conductive film PS1 left away from and around the conductive film PS1. The trenches W2 are each a linear trench. They are each a recess surrounded by the annular corner of the conductive film PS1.

As shown in FIG. 5, a character pattern CR1 made of trenches W4 in the conductive film PS1 is formed in each of the mark regions TR1 and TR2. The character patterns CR0 and CR1 are used to distinguish between different mark regions formed in the scribe region 1C. The character pattern CR1 represents, for example, a character string “AC”. Since the trenches W1 to W4 are openings in the laminated film including the insulating films CA and IO, conductive film PS1 and insulating film G0, the upper surface of the semiconductor substrate SB is exposed on the bottom of each of the trenches W1 to W4.

An explanation is given below of a case that the upper surface of the semiconductor substrate SB is partially exposed in the memory region 1A and scribe region 1C shown in FIG. 6 and the scribe region shown in FIG. 5 as mentioned above. The upper surface of the semiconductor substrate SB may be covered by a thin insulating film whose thickness is almost equal to that of the insulating film G0.

FIG. 5 shows that the left and right chip regions CP are covered by the conductive film PS1, but FIG. 6 shows that the chip region CP (FIG. 5) in the memory region 1A is not completely covered by the conductive film PS1.

As mentioned above, the pattern PT1 (PT2) is made of the trench W1 (trenches W2) made by partially removing the laminated film including the conductive film PS1 by etching. The width of the trench W1 (trenches W2), namely the length thereof in the direction perpendicular to the longitudinal direction thereof, is, for example, about 0.4 μm. The width of the scribe region 1C, namely the length thereof in the direction perpendicular to the longitudinal direction thereof is, for example, about 80 μm. The length of the mark region TR1 in the same direction as the width direction of the scribe region 1C is, for example, 10 to 50 μm and the length of the mark region TR1 in the longitudinal direction of the scribe region 1C is, for example, about 15 to 200 μm. The dimensions of the mark region TR2 are the same as those of the mark region TR1.

Thus, the width of the trench W1 (trenches W2) is very small as compared to the length of each side of the mark region TR1 (TR2). In other words, the area of the pattern PT1 in the mark region TR1 is small and the area of the pattern PT2 in the mark region TR2 is also small. Specifically, in the mark region TR1 used for inspection, the area of the pattern PT1, made by removing the conductive film PS1, is smaller than the area of the conductive film PS1 in a plan view. Likewise, in the mark region TR2 used for inspection, the area of the pattern PT2, made by removing the conductive film PS1, is smaller than the area of the conductive film PS1 in a plan view.

In other words, in the mark region TR2 used for positioning of the photo mask and in the mark region TR1 used for checking the position of a pattern made over the semiconductor substrate SB, the area of the region in which the conductive film PS1 is removed is smaller than the area of the region in which the conductive film PS1 is arranged.

Next, the positions of the patterns PT0 and PT1 are detected using an inspection optical instrument. This is carried out to check whether or not the select gate electrodes CG1 and CG2 are in the desired positions with respect to the semiconductor substrate SB which underlies the select gate electrodes CG1 and CG2.

As described above referring to FIGS. 5 and 6, the pattern PT1 is made in the same etching step using the same photo mask as the select gate electrodes CG1 and CG2. Also, as described referring to FIG. 1, the pattern PT0 is a pattern embedded in the trench made in the upper surface of the semiconductor substrate SB. Therefore, the positional relation between the select gate electrodes CG1 and CG2 and the element isolation region STI and active regions formed in the main surface of the semiconductor substrate SB underlying the electrodes can be checked by detecting the positions of the patterns PT0 and PT1.

Consequently, whether or not there is a positional defect in the patterns made by the processing steps described referring to FIGS. 5 and 6 with respect to the semiconductor substrate SB can be checked. If a defect due to a pattern positional error out of the allowable range is found by the above check, the manufacture of the semiconductor device which uses the semiconductor substrate bearing the pattern in question may be stopped or the above inspection result may be fed back to the manufacturing process to prevent recurrence of such defect to improve the reliability of the semiconductor device.

Next, as shown in FIG. 7, the insulating film CA is partially removed by the photolithographic technique or dry etching method. At this time, the insulating film CA in the peripheral circuit region 1B is removed. In the power feed region (not shown) for the select gate electrodes CG1 and CG2, the insulating film CA over the upper surfaces of the select gate electrodes CG1 and CG2 is removed. Consequently the region in which a contact plug made in a later step is coupled to the upper surface of each of the select gate electrodes CG1 and CG2 is exposed from the insulating film CA. If a PIP capacitive element is formed, the insulating film CA over the conductive film PS1 in the region in which the capacitive element is formed is removed.

At this time, the insulating film CA in the region exposed from the photoresist film (not shown) is removed. Since the above etching step is carried out with the memory region 1A and scribe region 1C covered by the photoresist film, the insulating film CA over the select gate electrodes CG1 and CG2 is not removed.

Although not shown, the insulating film CA immediately above a chip region CP shown in FIG. 5 and the element isolation regions STI at both ends of the scribe region 1C adjacent to one side of the chip region CP is also removed. In short, the insulating film CA in regions other than the regions surrounded by the trench W3 (FIG. 5) is removed. However, even in the chip region CP, some portion of the insulating film CA is left or not removed as in the memory region 1A (FIG. 6).

In the power feed region for the select gate electrodes CG1 and CG2, the insulating film CA must be removed accurately with respect to the select gate electrodes CG1 and CG2. The reason is that if the insulating film GA is inaccurately removed, the area for coupling with the contact plug on the upper surface of each of the select gate electrodes CG1 and CG2 would be too small, which might deteriorate the reliability of coupling between the select gate electrodes CG1 (CG2) and the contact plug and cause an increase in the contact resistance. Also, if the insulating film GA is inaccurately removed, shorting between the memory gate electrode formed in a later step and the select gate electrode CG1 or CG2 might occur in the above power feed region.

For this reason, the insulating film CA must be removed accurately with respect to the select gate electrodes CG1 and CG2. This means that the photoresist film used to remove the insulating film CA must be formed accurately with respect to the select gate electrodes CG1 and CG2. Therefore, the position of the photo mask used for exposure of the photoresist film to transfer a pattern must be determined accurately with respect to the select gate electrodes CG1 and CG2.

In order to adjust the position of the photo mask, the pattern PT2 as an alignment mark in the mark region TR2 (FIG. 5) is used. In the lithographic process, the pattern PT2 is detected using the optical instrument or the like provided in the exposure apparatus in which the photo mask and the semiconductor substrate SB are placed and alignment is made between the pattern PT2 and the photo mask. Since the pattern PT2 is the trench W2 made by the same etching step to form the select gate electrodes CG1 and CG2, a desired resist pattern of photoresist film can be formed with respect to the select gate electrodes CG1 and CG2 by adjusting the position of the photo mask using the pattern PT2 and the insulating film CA can be removed accurately.

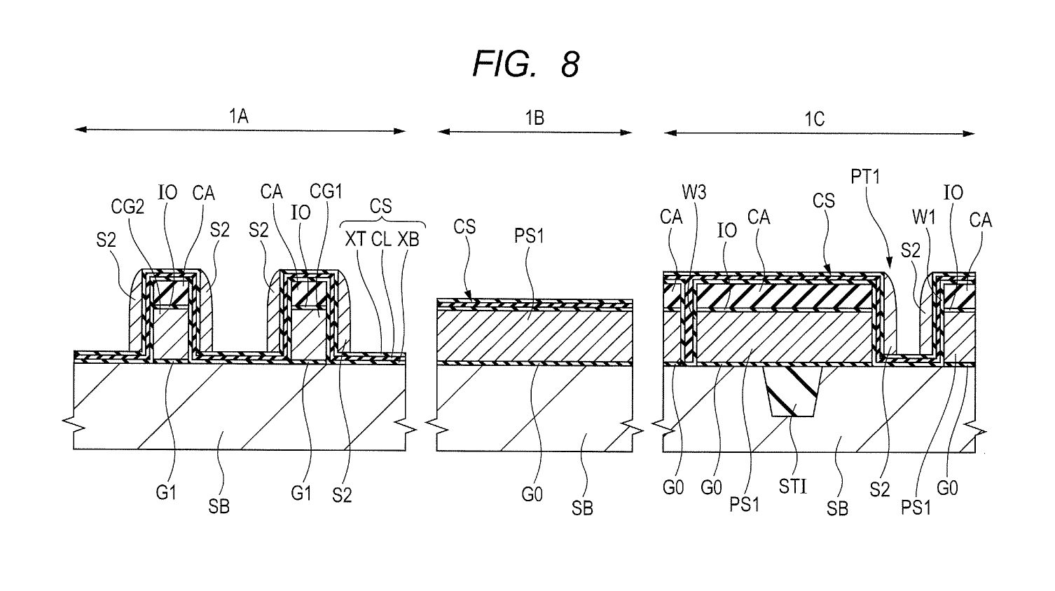

Next, as shown in FIG. 8, for example, an insulating film XB of silicon oxide, a charge storage layer CL of silicon nitride, and an insulating film XT of silicon oxide are formed over the main surface of the semiconductor substrate SB sequentially. The insulating film XB is formed by thermal oxidation or ISSG oxidation, for example, with a thickness of 1 to 10 nm, the charge storage layer CL is formed by CVD, for example, with a thickness of 5 to 20 nm, and the insulating film XT is formed by CVD or ISSG oxidation, for example, with a thickness of 4 to 15 nm. The insulating films XB and XT may be made of silicon oxide containing nitrogen. The insulating film XB, charge storage layer CL, and insulating film XT make up an ONO (Oxide Nitride Oxide) film CS.

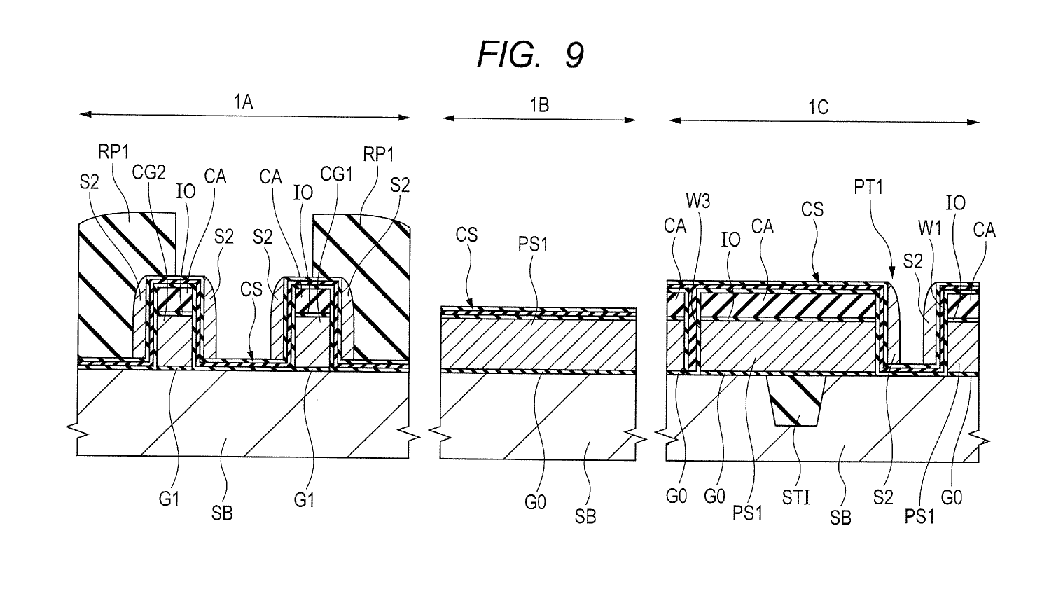

The insulating film IO over the conductive film PS1 in the peripheral circuit region 1B is assumed to be united with the insulating film XB, so the insulating film IO in the peripheral circuit region 1B is omitted in FIGS. 8 and 9. Although FIGS. 8 and 9 show that the trench W3 is completely filled with ONO film CS, the trench W3 need not be completely filled with ONO film CS.

Next, a conductive film of low-resistance polycrystalline silicon for the formation of a memory gate is deposited over the main surface of the semiconductor substrate SB. This conductive film is formed by CVD, for example, with a thickness of 50 to 100 nm. Then, anisotropic dry etching is done on this conductive film by the photolithographic and dry etching techniques to etch back the film.

Consequently, in the memory region 1A, sidewalls S2 of the conductive film are formed on both side faces of each of the laminated film including the insulating films CA and IO and select gate electrode CG1 and the laminated film including the insulating films CA and IO and select gate electrode CG2 in a self-aligning manner.

If a capacitive element is formed over the semiconductor substrate SB, the upper surface of the lower electrode is covered by ONO film CS and the upper surface of the ONO film CS is covered by the above conductive film in the capacitive element formation region (not shown). In the above etching step, the conductive film is etched as mentioned above with the conductive film over the ONO film CS partially covered by photoresist film to process the conductive film. Consequently, an upper electrode of the conductive film is formed immediately above the lower electrode through the ONO film CS.

Here, it is important that in the capacitive element formation region, the upper electrode is formed without misalignment with respect to the lower electrode of the conductive film PS1 processed in the same step (FIG. 6) in which the select gate electrodes CG1 and CG2 have been formed. If the upper electrode is not in alignment with the lower electrode, the area between the lower and upper electrodes facing each other through the ONO film CS would become small, resulting in reduction of the capacitance of the capacitive element.

For this reason, when forming the upper electrode by etching, the upper electrode must be accurately formed with respect to the lower electrode. Therefore, when forming a resist pattern of photoresist film for use in the above etching step, the position of the photo mask is adjusted using the pattern PT2 as the alignment mark shown in FIG. 5 in the same way as described above referring to FIG. 7. After that, exposure is performed and then the photoresist film is partially removed by a developing solution to form the above resist pattern. Then, the above conductive film is processed by carrying out an etching step using the photoresist film as a mask, to form the upper electrode.

Next, as shown in FIG. 9, in the memory region 1A, a photoresist film RP1 is formed so as to cover the select gate electrodes CG1 and CG2 partially and cover the sidewalls S2 partially. The photoresist film RP1 exposes a region adjacent to the first sidewall of the select gate electrode CG1 and covers a region adjacent to the second sidewall of the select gate electrode CG1. Similarly, the photoresist film RP1 exposes a region adjacent to the third sidewall of the select gate electrode CG2 and covers a region adjacent to the fourth sidewall of the select gate electrode CG2.

As for the facing sidewalls of the select gate electrodes CG1 and CG2 extending in parallel with each other, the sidewall of the select gate electrode CG1 is called the first sidewall and the sidewall of the select gate electrode. CG2 is called the third sidewall. The sidewall of the select gate electrode CG1 which is opposite to the first sidewall is called the second sidewall. The sidewall of the select gate electrode CG2 which is opposite to the third sidewall is called the fourth sidewall. In short, the select gate electrode CG1 has the first and second sidewalls in parallel with each other and the select gate electrode CG2 has the third and fourth sidewalls in parallel with each other.

Sidewalls S2 along the first and third sidewalls are exposed from the photoresist film RP1 and sidewalls S2 along the second and fourth sidewalls are covered by the photoresist film RP1. The photoresist film RP1 is a mask pattern used to remove the sidewalls S2 partially by anisotropic etching in a later step.

The peripheral circuit region 1B and scribe region 10 are not covered by the photoresist film RP1 and the sidewalls S2 are exposed in the scribe region 1C. If a capacitive element is formed over the semiconductor substrate, the region in which the capacitive element is formed is covered by the photoresist film RP1, though not shown.

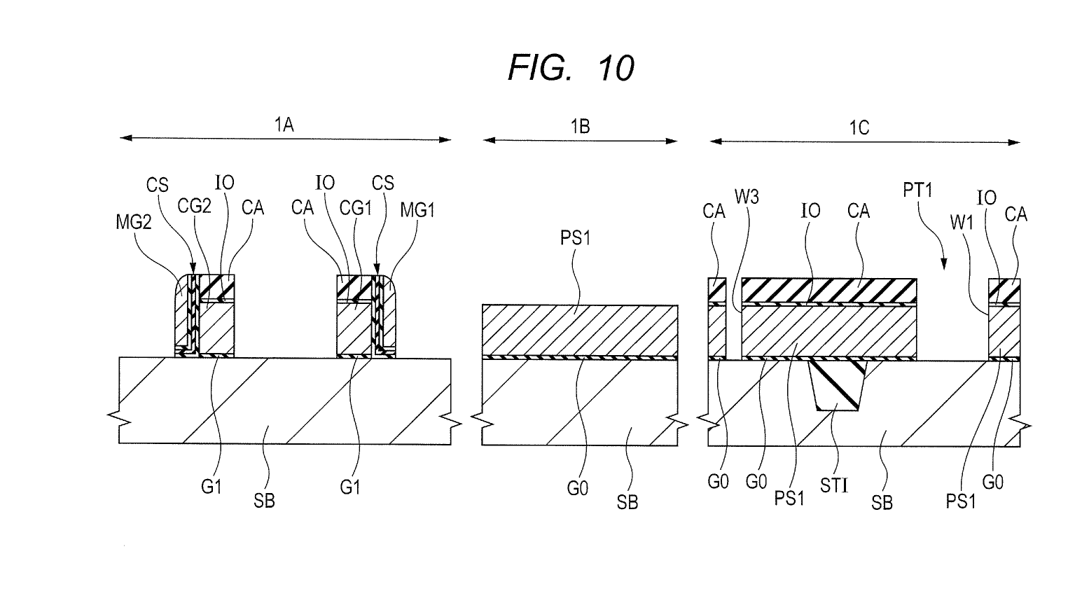

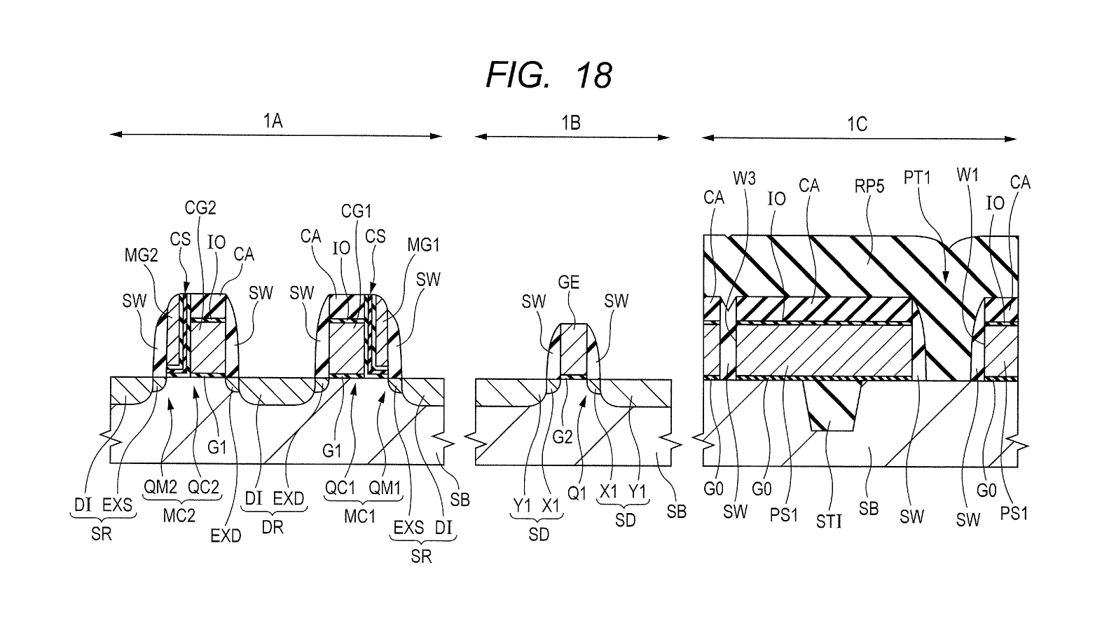

Next, as shown in FIG. 10, using the photoresist film RP1 (FIG. 9) as a mask, the sidewalls S2 exposed from the mask are removed by anisotropic etching such as wet etching. After that, the photoresist film RP1 is removed. Consequently, in the memory region 1A, a memory gate electrode MG1 for an n-type MISQM1 (FIG. 18) for memory which will be formed later is formed only on one side face of the laminated film including the insulating films CA and IO and select gate electrode CG1, namely the second sidewall.

Similarly, in the memory region 1A, a memory gate electrode MG2 for an nMISQM2 for memory (FIG. 18) which will be formed later is formed only on one side face of the laminated film including the insulating films CA and IO and select gate electrode CG2, namely the fourth sidewall. This •means that the memory gate electrodes MG1 and MG2 are comprised of the sidewalls S2. The gate length of each of the memory gate electrodes MG1 and MG2 is, for example, about 65 nm.

Next, in the memory region 1A, the ONO film CS is selectively removed by etching, in regions other than the region between the laminated film including the insulating films CA and IO and select gate electrode CG1 and the memory gate electrode MG1 and the region between the semiconductor substrate SB and memory gate electrode MG1. Also in the memory region 1A, the ONO film CS is selectively removed by etching, in regions other than the region between the laminated film including the insulating films CA and IO and select gate electrode CG2 and the memory gate electrode MG2 and the region between the semiconductor substrate SB and memory gate electrode MG2.

In the peripheral circuit region 1B and scribe region 1C, the conductive film PS1, and the ONO film CS covering the semiconductor substrate SB are removed in the above step. Consequently the surface of the conductive film PS1 is exposed in the peripheral circuit region 1B and the surface of the laminated film including the insulating films CA and IO and conductive film PS1 is exposed in the scribe region 1C.

If a capacitive element is formed in a region (not shown), the ONO film CS except the ONO film CS between the lower and upper electrodes is removed by selective etching in the region for formation of the capacitive element. Consequently, capacitive element including a lower electrode and an upper electrode is formed in which the ONO film CS is a capacitive insulating film, or dielectric film, and the lower electrode is made of the conductive film PS1 in the same layer as the select gate electrodes CG1 and CG2 and the upper electrode is made of the conductive film in the same layer as the memory gate electrodes MG1 and MG2.

In other words, the capacitive element includes the lower electrode, ONO film CS and upper electrode which are formed sequentially over the semiconductor substrate SB. The capacitive element includes, for example, a charge pump circuit used for a power supply circuit which supplies a higher voltage than input voltage. The charge pump circuit can increase the voltage by changing the connection states of plural capacitive elements using a switch, etc.

Here, the photoresist film RP1 used as a mask in the etching step described above referring to FIGS. 9 and 10 must be accurately positioned with respect to the select gate electrodes CG1 and CG2. The reason is that if the photoresist film RP1 is inaccurately positioned, it may happen that the sidewall S2 on one sidewall of each of the select gate electrodes CG1 and CG2 is not removed completely or that the sidewall S2 on the other sidewall of each of the select gate electrodes CG1 and CG2 is removed, namely the memory gate electrodes MG1 and MG2 are not left intact.

Therefore, in order to adjust the position of the photoresist film RP1 with respect to the select gate electrodes CG1 and CG2 accurately, the position of the photo mask for exposure of the photoresist film RP1 is adjusted using the pattern PT2 as the alignment mark shown in FIG. 5, in the same way as described above referring to FIG. 7. After that, exposure is performed and then the photoresist film RP1 is partially removed by a developing solution before the above etching step using the photoresist film RP1 as a mask to remove the sidewalls S2 partially. By adjusting the position of the photo mask using the alignment mark in this way, the photoresist film RP1 is prevented from failing to be formed in the desired position.

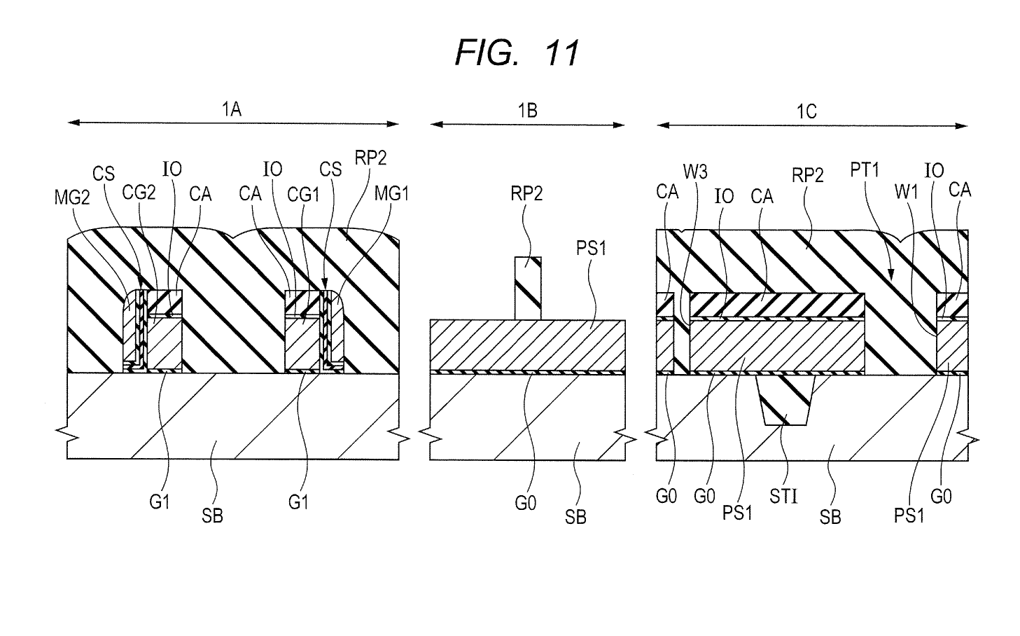

Next, as shown in FIG. 11, after n-type impurities are selectively doped into the conductive film PS1 in the peripheral circuit region 1B by the ion implanting method, a photoresist film RP2 is coated over the semiconductor substrate SB. Then, some portion of the conductive film PS1 in the peripheral circuit region 1B and the insulating film CA over some portion of the conductive film PS1 in the scribe region 1C are exposed from the photoresist film RP2 by exposure and development. In short, the photoresist film RP2 covers the memory region 1A and partially covers the peripheral circuit region 1B and scribe region 1C.

In the cross section of the scribe region 1C shown in FIG. 11, the photoresist film RP2 does not expose the insulating film CA. It is in a region not shown in FIG. 11, namely a mark region other than the mark regions TR1 and TR2 shown in FIG. 5, that the photoresist film RP2 partially exposes the insulating film CA in the scribe region 1C. The region in question will be described later referring to FIG. 13.

In the coated photoresist film RP2 in the mark region in question (not shown in FIG. 11), a rectangular frame-like opening is made in a plan view like the pattern PT1 in the mark region TR1 and the insulating film CA is exposed on the bottom of the opening. Though not shown in FIG. 11, the photoresist film RP2 may partially expose the conductive film PS1 immediately above the element isolation region STI (FIG. 5) at each end in the scribe region 1C, namely the element isolation region STI along one side of the chip region CP1.

As shown in FIG. 11, the laminated film including the insulating films CA and IO and conductive film PS1 covers almost the whole main surface of the semiconductor substrate SB in the scribe region 1C and the area of the pattern PT1 or PT2 in the mark region TR1 or TR2 is very small as compared to the laminated film. Therefore, in the scribe region 1C shown in FIG. 11, most of the photoresist film RP2 coated over the semiconductor substrate SB does not flow and stay inside and immediately above the trench W1 and the photoresist film RP1 mostly is arranged immediately above the conductive film PS1.

The thickness of the photoresist film RP2 immediately above the conductive film PS1 in the scribe region 1C is the same as the thickness of the photoresist film RP2 immediately above the select gate electrodes CG1 and CG2 in a region with plural gate electrodes densely formed over the semiconductor substrate SB, such as the memory region 1A. Also the thickness of the photoresist film RP2 immediately above the conductive film PS1 in the scribe region 1C is the same as the thickness of the photoresist film RP2 immediately above the conductive film PS1 in the peripheral circuit region 1B.

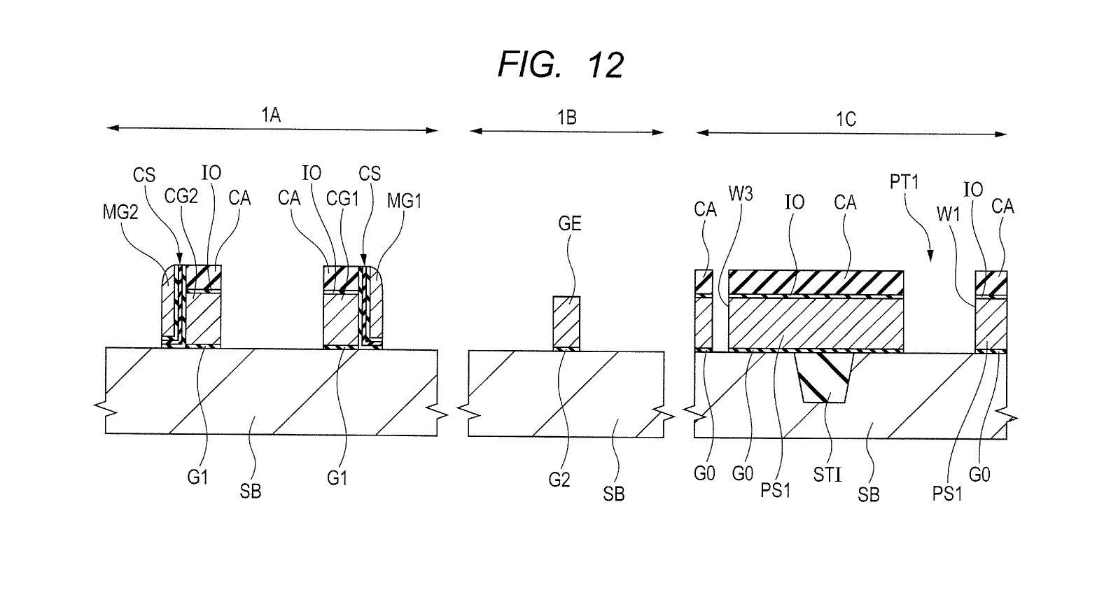

Next, as shown in FIGS. 12 and 13, a low-voltage nMIS gate electrode GE of conductive film PS1 and a gate insulating film G2 of insulating film G0 are formed by partially removing the conductive film PS1 and insulating film G0 in the peripheral circuit region 1B using the photoresist film RP2 as a mask by dry etching. In other words, the gate electrode GE is formed over the semiconductor substrate SB through the gate insulating film G2. As shown in FIG. 13, in the above step, a pattern PT3 as a trench W5 which exposes the upper surface of the semiconductor substrate SB is formed by removing the conductive film PS1 in the mark region TR3 of the scribe region 1C.

After that, the photoresist film RP2 over the semiconductor substrate SB is removed. The length of the gate electrode GE is, for example, about 100 nm.

Like the pattern PT1 as the trench W1 shown in FIGS. 5 and 6, the pattern PT3 in the scribe region 1C is the trench W5 made by partially removing the laminated film including the insulating films CA and IO and conductive film PS1 in the mark region TR3 of the scribe region 1C. In the mark region TR3, a pattern PT0 made of an annular element isolation region STI is formed in the main surface of the semiconductor substrate SB as in the mark region TR1. In short, the mark region TR3 is structurally the same as the mark region TR1 shown in FIG. 5. The pattern PT3 in the mark region TR3 is used to check the position of a pattern in the peripheral circuit region 1B, such as a gate electrode GE, as described later.

Although FIG. 12 shows one gate electrode GE in the peripheral circuit region 1B, actually a plurality of gate electrodes GE is arranged side by side, for example, in the gate length direction. These gate electrodes GE are used not only for low-voltage n-type MISFETs but also low-voltage p-type MISFETs. Although the figure shows a pair of select gate electrodes CG1 and CG2 in the memory region 1A, actually a plurality of select gate electrodes is densely arranged side by side and a memory gate electrode is formed adjacent to one sidewall of each select gate electrode.

After that, the positions of the patterns PT0 and PT3 are detected using an inspection optical instrument. By doing so, whether or not a gate electrode GE is in the desired position with respect to the semiconductor substrate SB under the gate electrode is checked.

As described referring to FIGS. 11, 12 and 13, the pattern PT3 is a pattern which is made by the same etching step using the same photo mask as the gate electrode GE. Also, the pattern PT0 is a pattern embedded in the trench in the upper surface of the semiconductor substrate SB. Therefore, the positional relation between the gate electrode GE and the element isolation region STI and active regions formed in the main surface of the semiconductor substrate SB under the gate electrode can be checked by detecting the positions of the patterns PT0 and PT3.

Thus, whether or not the patterns made by the processing steps described above referring to FIGS. 11, 12 and 13 are each in the desired position with respect to the semiconductor substrate SB can be checked. If a defect due to a pattern positional error out of the allowable range is found by the above check, the manufacture of the semiconductor device which uses the semiconductor substrate with the pattern in question may be stopped or the above inspection result may be fed back to the manufacturing process to prevent recurrence of such defect and improve the reliability of the semiconductor device.

Alternatively, in order to check the positional relation between the select gate electrodes CG1 and CG2 formed by processing the conductive film PS1 in the step described above referring to FIGS. 5 and 6 and the gate electrode GE formed by processing the conductive film PS1 in the step described referring to FIGS. 12 and 13, the pattern PT1 (FIG. 5) and pattern PT3 (FIG. 13) may be inspected to check whether or not there is a pattern misalignment.

In this case, patterns PT1 and PT3 may be formed in a mark region other than the mark region TR1 (FIG. 5) and mark region TR3 (FIG. 13) to compare the positions of these patterns. Specifically, after forming an annular pattern PT1 in the other mark region by the step described referring to FIGS. 5 and 6, an annular pattern PT3 may be formed inside the annular pattern PT1 in the other mark region by the step described referring to FIGS. 12 and 13.

Next, though not shown, after an insulating film of, for example, silicon oxide with a thickness of about 10 nm is deposited over the main surface of the semiconductor substrate SB by CVD, the insulating film is etched back by anisotropic dry etching. Consequently, in the memory region 1A, sidewalls (not shown) are formed on the side face opposite to the memory gate electrode MG1 of the laminated film including the insulating films CA and IO and select gate electrode CG1 and the side face of the memory gate electrode MG1. Similarly, in the memory region 1A, sidewalls (not shown) are formed on the side face opposite to the memory gate electrode MG2 of the laminated film including the insulating films CA and IO and select gate electrode CG2 and the side face of the memory gate electrode MG2.

In the peripheral circuit region 1B, the above sidewalls are thus formed on bot side faces of the gate electrode GE. Also, sidewalls are formed on the side faces of the trenches W1 and W3 in the scribe region 1C. The spacer length of a sidewall is, for example, about 6 nm. Due to the formation of these sidewalls, in the step of forming an n −type semiconductor region in, a low-voltage nMIS formation region of the peripheral circuit region 1B (described later), the effective channel length of the n −type semiconductor region increases, thereby suppressing the short channel effect of the low-voltage nMIS. In short, the sidewalls are used as offset spacers.

As shown in FIG. 14, a photoresist film RP3, with one end lying on the upper surface of the select gate electrode CG1 in the memory region 1A, is formed, covering the memory gate electrode MG1 and a memory gate electrode MG1 side portion of the select gate electrode CG1. The photoresist film RP3, with the other end lying on the upper surface of the select gate electrode CG2 in the memory region 1A, covers the memory gate electrode MG2 and a memory gate electrode MG2 side portion of the select gate electrode CG2. In short, the photoresist film RP3 is a pattern which makes an opening between the first sidewall of the select gate electrode CG1 and the third sidewall of the select gate electrode CG2 and covers the other regions.

After that, n-type impurities (for example, As (arsenic)) are doped into the main surface of the semiconductor substrate SB by ion implanting using the select gate electrodes CG1 and CG2 and photoresist film RP3 as a mask to form an n −type semiconductor region EXD in the main surface of the semiconductor substrate SB in a self-aligning manner with respect to the select gate electrodes CG1 and CG2.

The photoresist film RP3 must terminate immediately above the upper surfaces of the select gate electrodes CG1 and CG2. In order to form the n −type semiconductor region EXD in the desired region, the photoresist film RP3 must be accurately positioned with respect to the select gate electrodes CG1 and CG2.

Therefore, the photo mask for exposure of the photoresist film RP3 is positioned using the pattern PT2 as the alignment mark shown in FIG. 5, in the same way as described above referring to FIG. 7. After that, exposure is performed, and then the photoresist film RP3 is partially removed by a developing solution before the above ion implanting step using the photoresist film RP3 as a mask to form the n −type semiconductor region EXD. By adjusting the position of the photo mask using the alignment mark in this way, the photoresist film RP3 is prevented from failing to be formed in the desired position.

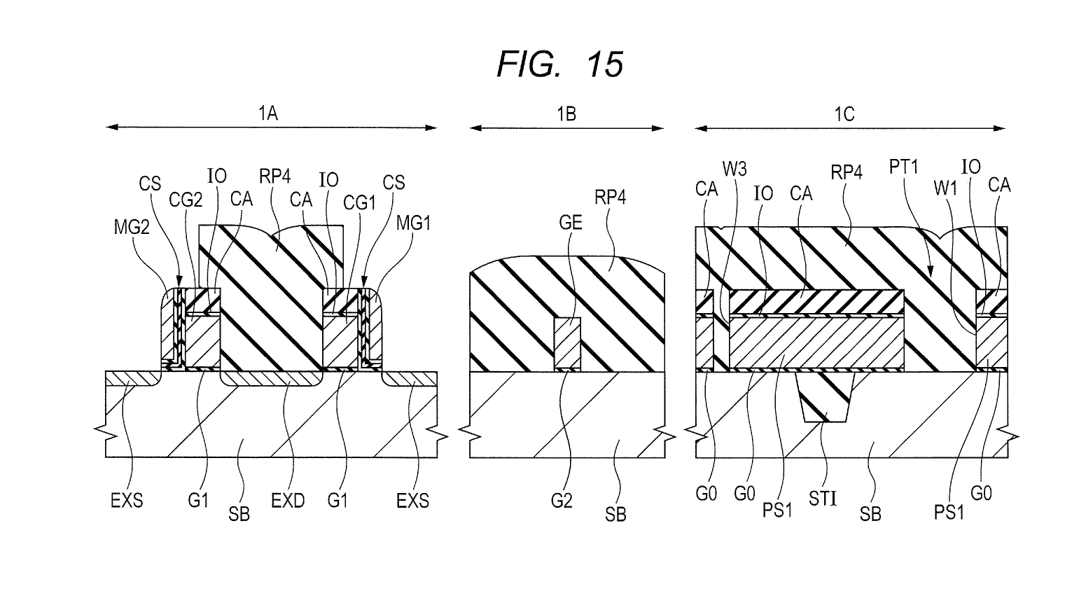

Next, as shown in FIG. 15, after removal of the photoresist film RP3, a photoresist film RP4 with one end lying on the upper surface of the select gate electrode CG1 in the memory region 1A is formed, covering a portion of the select gate electrode CG1 opposite to the memory gate electrode MG1. The photoresist film RP4, with the other end lying on the upper surface of the select gate electrode CG2 in the memory region 1A, covers a portion of the select gate electrode CG2 opposite to the memory gate electrode MG2. In short, the photoresist film RP4 exposes the active regions on the second sidewall of the select gate electrode CG1 and the fourth sidewall of the select gate electrode CG2. Also the photoresist film RP4 covers the peripheral circuit region 1B and scribe region 1C.

After that, n-type impurities (for example, As (arsenic)) are doped into the main surface of the semiconductor substrate SB by ion implanting using the select gate electrodes CG1 and CG2, memory gate electrodes MG1 and MG2, and photoresist film RP4 as a mask to form an n −type semiconductor region EXS in the main surface of the semiconductor substrate SB in a self-aligning manner with respect to the memory gate electrodes MG1 and MG2.

The photoresist film RP4 must terminate immediately above the upper surfaces of the select gate electrodes CG1 and CG2. In order to form the n −type semiconductor region EXS in the desired region, the photoresist film RP4 must be accurately positioned with respect to the select gate electrodes CG1 and CG2. Therefore, the position of the photo mask is adjusted using the pattern PT2 as the alignment mark (FIG. 5), in the same way as described referring to FIG. 7. Consequently the photoresist film RP4 is prevented from failing to be formed in the desired position.

Although the n −type semiconductor region EXD is formed before formation of the n −type semiconductor region EXS in this case, instead the n −type semiconductor region EXS may be formed before formation of the n −type semiconductor region EXD. Alternatively, after implantation of n-type impurity ions to form the n −type semiconductor region EXD, p-type impurities (for example, B (boron)) may be doped into the main surface of the semiconductor substrate SB by ion implanting to form a p-type semiconductor region in a deeper region than the n −type semiconductor region EXD.

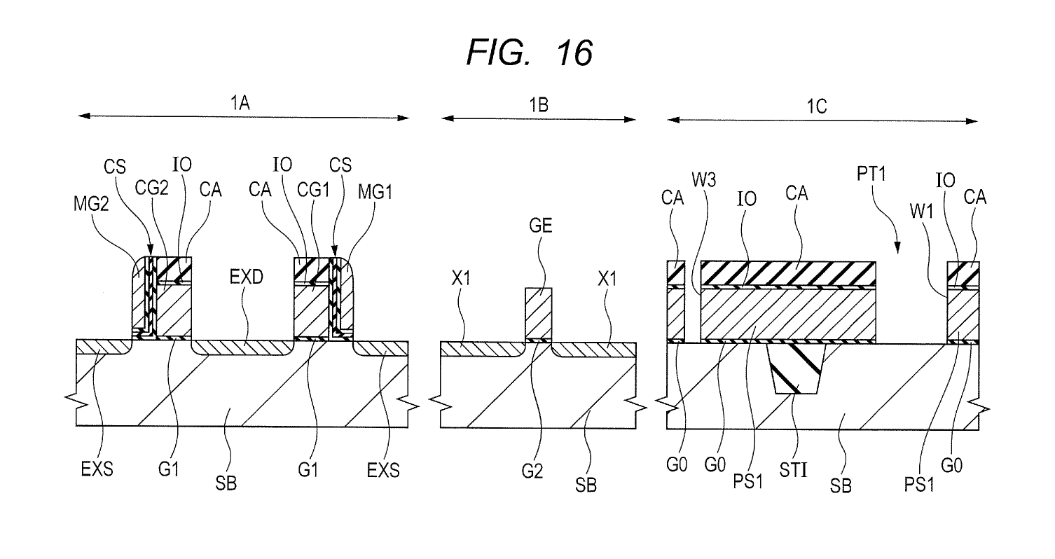

As shown in FIG. 16, after removal of the photoresist film RP4, n-type impurities (for example, As (arsenic)) are doped into the main surface of the semiconductor substrate SB in the peripheral circuit region 1B by ion implanting using a photoresist film (not shown) as a mask to form an n −type semiconductor region X1 in the main surface of the semiconductor substrate SB in the peripheral circuit region 1B in a self-aligning manner with respect to the gate electrode GE.

Again, in order to form the n −type semiconductor region X1 in the desired position, the above photoresist film (not shown) must be accurately positioned with respect to the gate electrode GE. Therefore, the position of the photo mask is adjusted using the alignment mark in the same way as described referring to FIG. 7.

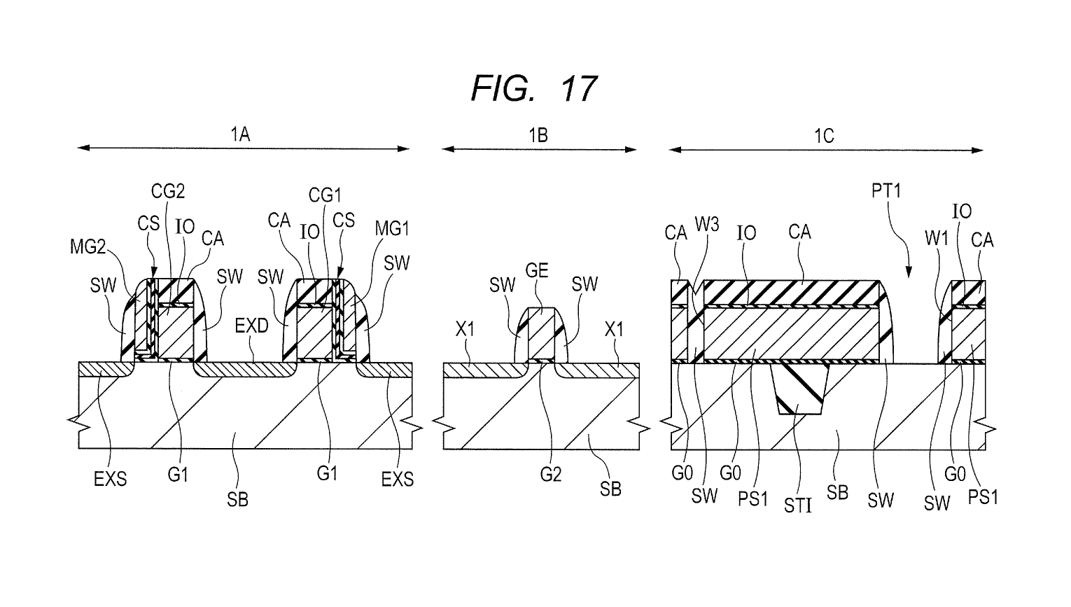

Next, as shown in FIG. 17, for example, a silicon oxide film and a silicon nitride film are deposited sequentially over the main surface of the semiconductor substrate SB by CVD and these films are etched back by anisotropic dry etching. Consequently, in the memory region 1A, sidewalls SW of the silicon oxide and silicon nitride films are formed on both side faces of the structural body which includes the laminated film including the insulating films CA and IO and select gate electrode CG1, the ONO film CS and the memory gate electrode MG1. Similarly, in the memory region 1A, sidewalls SW of the silicon oxide and silicon nitride films are formed on both side faces of the structural body which includes the laminated film including the insulating films CA and IO and select gate electrode CG2, and the ONO film CS and the memory gate electrode MG2.

Similarly, in the peripheral circuit region 1B, sidewalls SW are formed on both side faces of the gate electrode GE. The thickness of the silicon oxide film is, for example, 20 nm and the thickness of the silicon nitride film is, for example, 25 nm. For easy understanding, FIG. 17 does not show the silicon oxide and silicon nitride films but shows each sidewall SW as a single layer though it is a laminate of these films.

Next, as shown in FIG. 18, a photoresist film RP5 covering the scribe region 1C is formed. After that, n-type impurities (for example, As (arsenic) or P (phosphorous)) are doped into the main surface of the semiconductor substrate SB in the memory region 1A and peripheral circuit region 1B by ion implanting using the photoresist film RP5 as a mask. By carrying out the above ion implanting step, an n + type semiconductor region DI is formed in the memory region 1A in a self-aligning manner with respect to the select gate electrodes CG1 and CG2 and memory gate electrodes MG1 and MG2 and an n + type semiconductor region Y1 is formed in the peripheral circuit region 1B in a self-aligning manner with respect to the low-voltage nMIS gate electrode GE.

Consequently, a drain region DR including the n −type semiconductor region EXD and n + type semiconductor region DI and a source region SR including the n −type semiconductor region EXS and n + type semiconductor region DI are formed in the memory region 1A. Also, a source/drain region SD including the n −type semiconductor region EX1 and n + type semiconductor region Y1 is formed in the peripheral circuit region 1B.

In this step, an nMISQC1 for selection including the select gate electrode CG1, source region SR, and drain region DR and an nMISQC2 for selection including the select gate electrode CG2, source region SR, and drain region DR are formed in the memory region 1A. Also, an nMISQM1 for memory including the memory gate electrode MG1, source region SR, and drain region DR and an nMISQM2 for memory including the memory gate electrode MG2, source region SR, and drain region DR are formed in the memory region 1A. The nMISQC1 for selection and nMISQM1 for memory make up a split-gate MONOS memory cell MC1 and the nMISQC2 for selection and nMISQM2 for memory make up a split-gate MONOS memory cell MC2.

In the peripheral circuit region 1B, a low-voltage nMISQ1 including the gate electrode GE and source/drain region SD is formed.

Again, in order to accurately form the photoresist film RP5 so as to cover the scribe region 1C, when making a resist pattern of photoresist film RP5, the position of the photo mask is adjusted using the alignment mark before an exposure step.

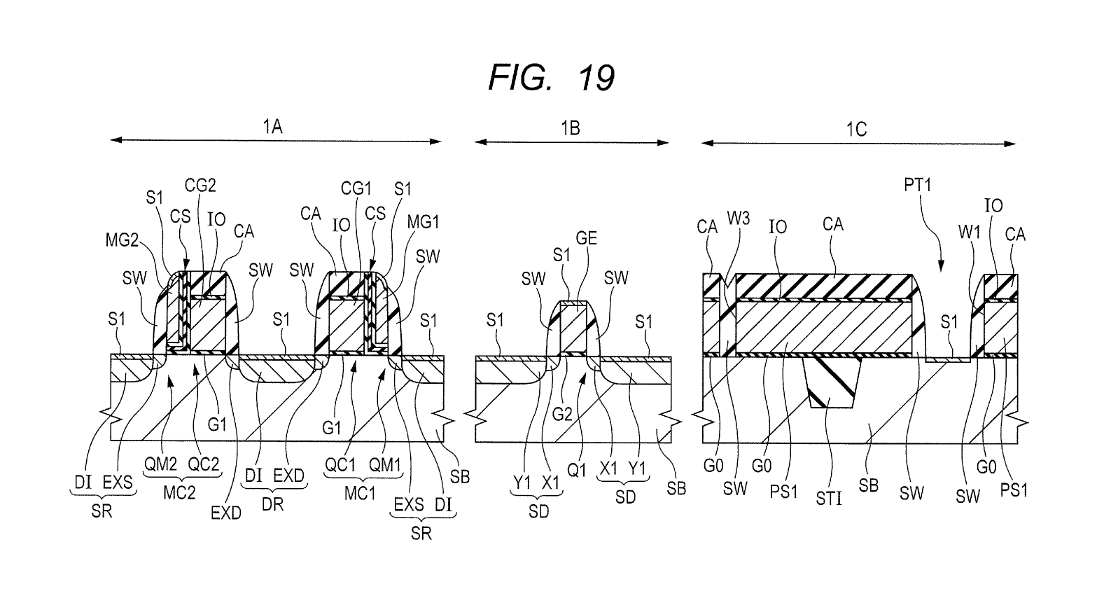

Next, as shown in FIG. 19, in the memory region 1A, a silicide layer S1 is formed on the upper surfaces of the memory gate electrodes MG1 and MG2, and n + type semiconductor regions DI. In the power feed region (not shown) for the select gate electrodes CG1 and CG2, a silicide layer S1 is formed on the upper surfaces of the select gate electrodes CG1 and CG2 which are exposed from the insulating films CA and IO. If a capacitive element is formed, a silicide layer S1 is formed on the upper surface of the upper electrode and the upper surface of the lower electrode exposed from the upper electrode in a region not overlapping the sidewalls SW in a plan view, though not shown.

In the peripheral circuit region 1B, a silicide layer S1 is formed on the upper surface of the low-voltage nMIS gate electrode GE and the upper surface of the n + type semiconductor region Y1. A silicide layer S1 is formed by a salicide (Self Align silicide) process. For example, a nickel silicide or cobalt silicide is used as the material of the silicide layer S1.

The silicide layer S1 reduces the contact resistance between the silicide layer S1 and a plug, etc. formed over it. Furthermore, in the memory region 1A, the silicide layer S1 reduces the resistances of the memory gate electrodes MG1 and MG2 and source regions SR and drain regions DR. In the peripheral circuit region 1B, it reduces the resistance of the low-voltage nMIS gate electrode GE and the resistance of the source/drain region SD.

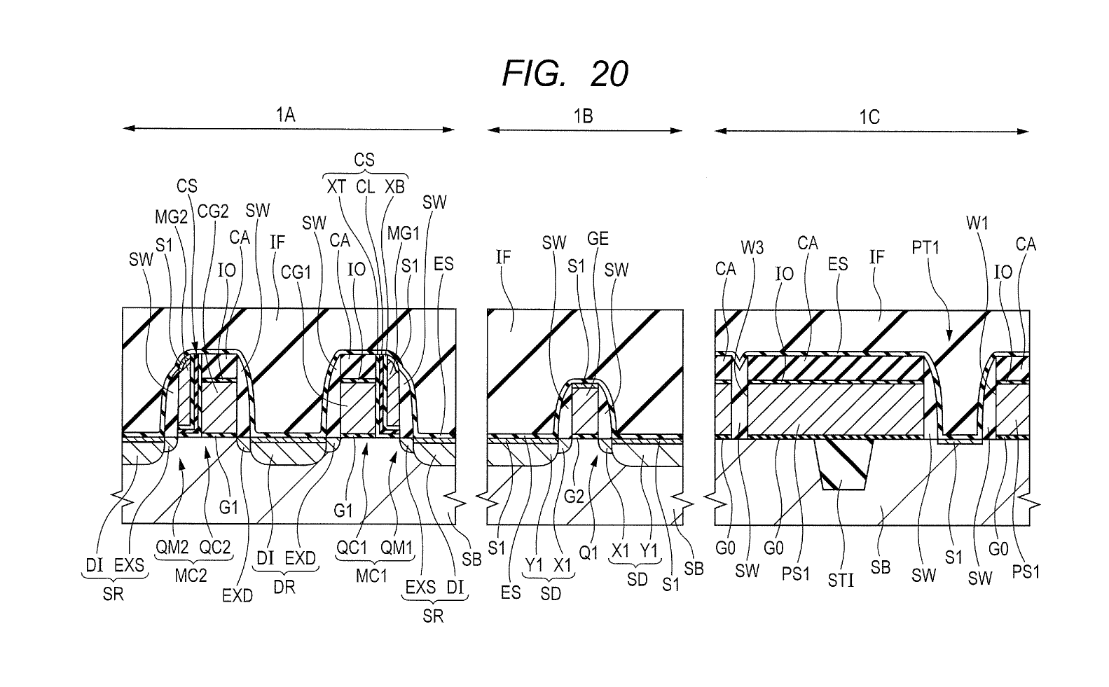

Next, as shown in FIG. 20, a silicon nitride film ES as an insulating film is deposited over the main surface of the semiconductor substrate SB by CVD. The silicon nitride film ES functions as an etching stopper used in making a contact hole (described later). Then, after deposition of a silicon oxide film IF as an insulating film by CVD, the upper surface of the silicon oxide film IF is planarized by CMP. Consequently an interlayer insulating film, including the silicon nitride film ES and silicon oxide film IF, is formed.

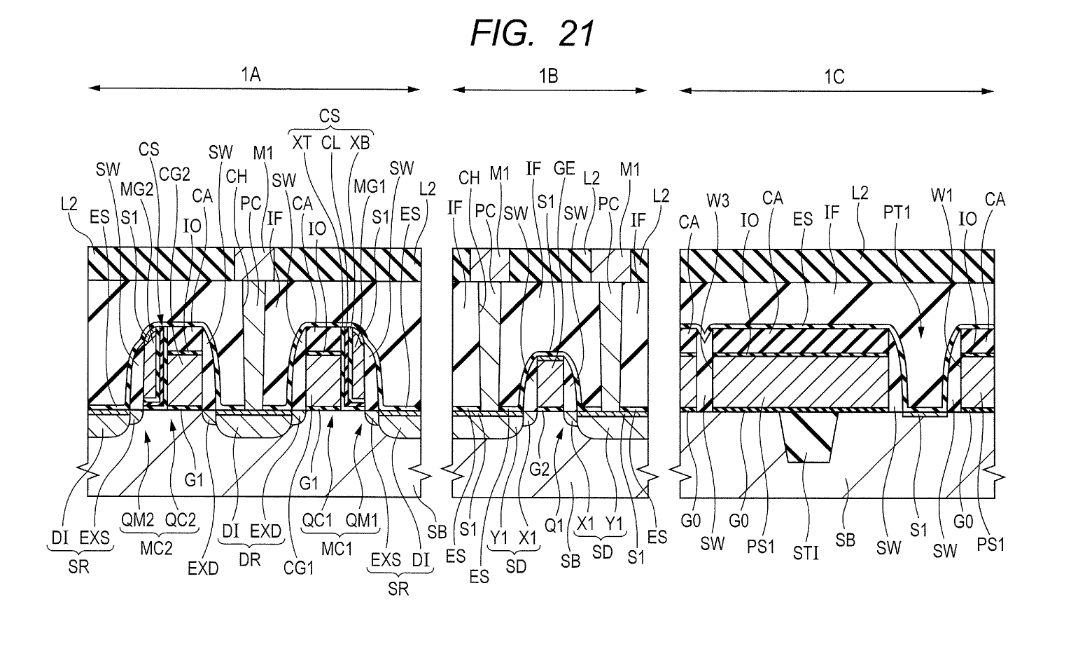

Next, as shown in FIG. 21, a plurality of contact holes CH which reach the silicide layer S1 over the drain region DR and the silicide layer S1 over the source/drain region SD are made in the above interlayer insulating film. In the power feed region (not shown) for the select gate electrodes CG1 and CG2, contact holes CH which reach the silicide layers S1 over the select gate electrodes CG1 and CG2 which are exposed from the insulating films CA and IO are made.

After that, a plug of conductive material is embedded in each contact hole CH. Plugs PC are embedded in the contact holes respectively.

If a capacitive element is formed over the semiconductor substrate SB, contact holes CH which reach the silicide layers S1 on the upper surface of the upper electrode and the upper surface of the lower electrode are made in regions which the upper electrode and lower electrode of the capacitive element do not overlap in a plan view before plugs PC are embedded in the contact holes CH respectively, though not shown.

In a region not shown in the figure, a plug PC coupled to the upper surfaces of the source region SR and gate electrode GE is formed in a contact hole CH.

A plug PC is made of a laminated film which includes a relatively thin barrier film as a laminated film of Ti (titanium) and Tin (titanium nitride) and a relatively thick conductive film of W (tungsten) or Al (aluminum) enveloped by the barrier film. For easy understanding, FIG. 21 shows a plug PC as a single layer film though it has a laminated structure as mentioned above.

After that, an interlayer insulating film L2, for example, an SiOC film, is formed over the above interlayer insulating film by CVD or a similar method. Then, a trench is made in the interlayer insulating film L2 by the photolithographic technique or dry etching method to expose the upper surface of the plug PC and then a Cu (copper) or Al (aluminum) based first layer wiring M1 is formed in the trench so that a semiconductor device according to this embodiment is completed. After that, ordinary steps of manufacturing a semiconductor device are carried out to produce a semiconductor device with a nonvolatile memory.

Next, the structures of memory cells MC1 and MC2 which include a split gate MONOS memory as a nonvolatile memory according to this embodiment will be described referring to FIG. 21.

As shown in FIG. 21, the memory cells MC1 and MC2 are linearly symmetrical with each other. So, hereinafter, focus will be mainly put on the structure of the memory cell MC1 and descriptions of the structures of the memory cell MC2, nMISQC2 for selection and nMISQM2 for memory will be sometimes omitted.

The drain region DR of the memory cell MC1 has an LDD (Lightly Doped Drain) structure which includes, for example, a relatively low-concentration n −type semiconductor region EXD and a relatively high-concentration n + type semiconductor region DI with a doping concentration higher than that of the n −type semiconductor region EXD. The source regions SR of the memory cells MC1 and MC2 have an LDD structure which includes, for example, relatively low-concentration n −type semiconductor region EXS and a relatively high-concentration n + type semiconductor region DI with a doping concentration higher than that of the n −type semiconductor region EXS. The n −type semiconductor regions EXD and EXS are located on the channel region side of the memory cell MC1 (MC2) and the n + type semiconductor region DI is located away from the channel region of the memory cell MC1 (MC2) by a distance equivalent to the n −type semiconductor region EXD or EXS.

The select gate electrode CG1 of the nMISQC1 for selection and the memory gate electrode MG1 of the nMISQM1 for memory are located adjacent to each other over the main surface of the semiconductor substrate SB between the drain region DR and source region SR. The insulating film CA is arranged over the upper surface of the select gate electrode CG1 through the insulating film IO.

The memory gate electrode MG1 is arranged adjacent to one side face of the laminated film including the insulating films CA and IO and select gate electrode CG1, like a sidewall. No memory gate electrode MG1 is formed on the first sidewall of the select gate electrode CG1 and a memory gate electrode MG1 is formed adjacently to the second sidewall of the select gate electrode CG1. The select gate electrode CG1 is made of, for example, n-type low-resistance polycrystalline silicon and the gate length of the select gate electrode CG1 is, for example, about 80 to 120 nm. The memory gate electrode MG1 is made of a second conductive film, for example, n-type low-resistance polycrystalline silicon and the gate length of the memory gate electrode MG1 is, for example, about 50 to 100 nm.

The insulating film 10 is, for example, a silicon oxide film. The insulating film CA is, for example, an insulating film of silicon nitride, silicon oxide, nitrogen-containing silicon oxide or nitrogen-containing silicon carbide and its thickness is, for example, about 50 nm. The height of the upper surface of the select gate electrode CG1 from the main surface of the semiconductor substrate SB is, for example, about 140 nm and the height of the upper surface of the memory gate electrode MG1 from the main surface of the semiconductor substrate SB is about 50 nm larger than that of the upper surface of the select gate electrode CG1.

The silicide layer S1 of, for example, nickel silicide (NiSi) or cobalt silicide (CoSi₂) is arranged on the upper surface of the memory gate electrode MG1. The thickness of the silicide layer S1 is, for example, about 20 nm. In a split gate nonvolatile memory cell, voltage must be supplied to both the select gate electrode CG1 and memory gate electrode MG1 and its operation speed largely depends on the resistances of the select gate electrode CG1 and memory gate electrode MG1. Therefore, it is desirable that the resistances of the select gate electrode CG1 and memory gate electrode MG1 be lowered by formation of the silicide layer S1.

On the other hand, in the active region, the silicide layer S1 is arranged only on the upper surface of the memory gate electrode MG1 and does not exist on the upper surface of the select gate electrode CG1. Even though the silicide layer does not exist on the upper surface of the select gate electrode CG1 in the active region, the desired operation speed can be achieved by lowering the resistance of the conductive film of the select gate electrode CG1. The silicide layer S1 also is arranged on the upper surface of the n + type semiconductor region DI of the source region SR or drain region DR. In the power feed region not shown in FIG. 21, the silicide layer S1 is arranged on the upper surface of the select gate electrode CG1.

The gate insulating film G1 is arranged between the select gate electrode CG1 and the main surface of the semiconductor substrate SB. The gate insulating film G1 is made of, for example, silicon oxide and its thickness is, for example, about 1 to 5 nm. A p-well (not shown) is formed in the main surface of the semiconductor substrate SB under the gate insulating film G1.

The memory gate electrode MG1 is arranged on a side face of the select gate electrode CG1 through the gate insulating film, namely ONO film CS. The ONO film CS, which isolates the memory gate electrode MG1 from the select gate electrode CG1, is a laminated film including the insulating film XB, charge storage layer CL, and insulating film XT. The memory gate electrode MG1 is arranged over the semiconductor substrate SB through the ONO film CS.

The charge storage layer CL is made of, for example, silicon nitride and its thickness is, for example, about 5 to 20 nm. The insulating films XB and XT are made of, for example, silicon oxide and the thickness of the insulating film XB is, for example, about 1 to 10 nm and the thickness of the insulating film XT is, for example, about 4 to 15 nm. The insulating films XB and XT may be made of nitrogen-containing silicon oxide.

In this embodiment, an insulating film having a trap level is used as the charge storage layer CL. One example of the insulating film having a trap level is silicon nitride film as mentioned above. However, it is not limited to silicon nitride film and instead it may be high dielectric constant film whose dielectric constant is higher than that of silicon nitride film, such as aluminum oxide film (alumina), hafnium oxide film, or tantalum oxide film.

A first layer wiring M1 extending in the second direction perpendicular to the first direction in which the select gate electrode CG1 extends is coupled to the drain region DR through the plug PC embedded in the contact hole CH.

Next, writing, erasing, and reading in the memory cell MC1 will be described referring to FIG. 21. Here, “write” is defined as injection of electrons into the ONO film CS and “erase” is defined as injection of holes.

For write operation, the hot electron write method called the source-side injection method is adopted. In write operation, for example, 0.7 V, 10 V, 6V, 0 V, and 0 V are applied to the select gate electrode CG1, memory gate electrode MG1, source region SR, drain region DR, p-well (not shown) respectively. Consequently, hot electrons are generated in the middle region between the select gate electrode CG1 and memory gate electrode MG1, in the channel region between the source region SR and drain region DR, and injected into the ONO film CS. The injected electrons are trapped by the trap in the silicon nitride film of the charge storage layer CL so that the threshold voltage of the memory cell MC1 increases.

For erase operation, the hot hole injection erasing method which uses a channel current is adopted. In erase operation, for example, 0.7 V, −8 V, 7 V, 0 V, and 0 V are applied to the select gate electrode CG1, memory gate electrode MG1, source region SR, drain region DR, and p-well respectively. Consequently a channel region is formed in the p-well under the select gate electrode CG1.

Since high voltage (7 V) is applied to the source region SR, the depletion layer extending from the source region SR comes closer to the channel region of the nMISQC1 for selection. As a result, electrons flowing in the channel region are accelerated by the high electric field between the channel region end and the source region SR and impact-ionized, thereby generating electron-hole pairs. Then the holes are accelerated by the negative voltage (−8 V) applied to the memory gate electrode MG1 to become hot holes before being injected into the ONO film CS. The injected holes are trapped by the trap in the charge storage layer CL so that the threshold voltage of the nMISQM1 for memory decreases.

In read operation, for example, 1.5 V, 1.5 V, 0 V, 1.5 V, and 0 V are applied to the select gate electrode CG1, memory gate electrode MG1, source region SR, drain region DR, and p-well respectively. In other words, the voltage applied to the memory gate electrode MG1 is set between the threshold voltage of the nMISQM1 for memory in the write state and the threshold voltage of the nMISQM1 for memory in the erase state to distinguish between the write state and erase state.

In this embodiment, a nonvolatile memory including memory cells MC1 and MC2, a MISFET for a peripheral circuit, and a mark for inspection are formed over a single semiconductor substrate. The select gate electrodes CG1 and CG2 of the memory cells MC1 and MC2, and the gate electrode GE of the low-voltage nMISQ1 in the peripheral circuit region 1B are formed by processing the same conductive film PS1 (FIG. 4). In this case, the select gate electrodes CG1 and CG2 are first formed and then the ONO film CS and memory gate electrodes MG1 and MG2 are formed before the formation of the gate electrode GE.

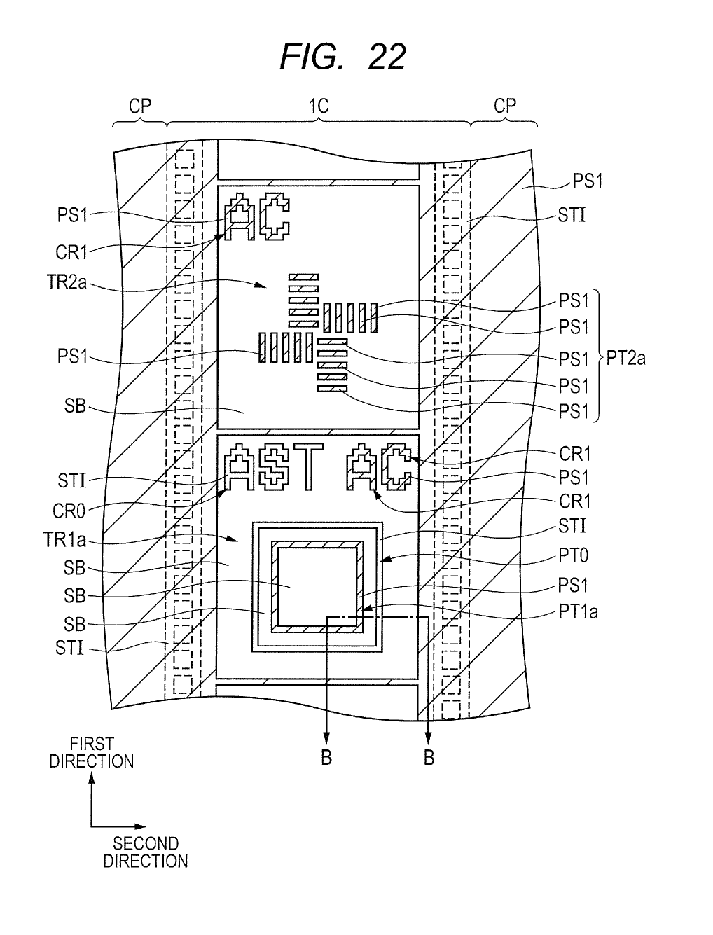

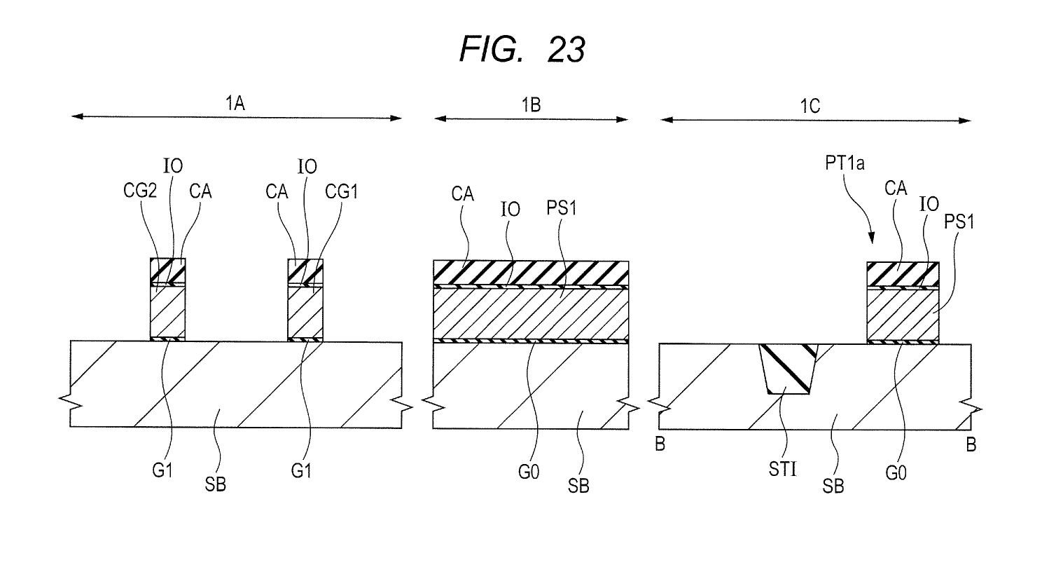

Next, the advantageous effects of the semiconductor device manufacturing method according to this embodiment will be explained referring to FIGS. 22 to 25 which show a comparative example. FIG. 22 is a plan view of a semiconductor device manufacturing process according to the comparative example and FIGS. 23 to 25 are sectional views of the semiconductor device manufacturing process.

In the embodiment explained so far, the alignment mark used to adjust the position of the photo mask in the lithographic process or the inspection mark to check the position of a pattern such as a gate electrode formed over the substrate is a trench made by partially removing a film. On the other hand, another method is possible in which the alignment mark or inspection mark is not a linear trench but a linear film pattern like a gate electrode.

Next the semiconductor device manufacturing process according to the comparative example will be described in which most of the film in the mark region is removed and a linear pattern of remaining film is used as an inspection mark. In the comparative example as well, as in the above embodiment, after select gate electrodes in a memory region are formed by processing a given conductive film, the conductive film is further processed to form a MISFET gate electrode in a peripheral circuit region.

In the comparative example, the steps described earlier referring to FIGS. 1 to 4 are first carried out. Specifically, as shown in FIG. 1, an element isolation region STI including a pattern PT0 is formed in the main surface of the semiconductor substrate SB and then as shown in FIG. 4, an insulating film G0, conductive film PS1, and insulating films IO and CA are formed over the semiconductor substrate SB sequentially.

Next, as shown in FIGS. 22 and 23, the insulating films CA and IO, conductive film PS1, and insulating film G0 in the memory region 1A and scribe region 1C are processed to form select gate electrodes CG1 and CG2 and a gate insulating film G1 in the memory region 1A and form a pattern PT1a of conductive film PS1 in the scribe region 10. Across section of the scribe region 10 taken along the line B-B of FIG. 22 is shown in FIG. 23.

As shown in FIG. 22, in a mark region TR1a in the scribe region 10, an annular pattern PT1a of conductive film PS1 is formed inside the pattern PT0 in a plan view. In a mark region TR2a in the scribe region 10, a pattern PT2a is formed in which a plurality of conductive films PS1 extending in a direction are arranged in a direction perpendicular to that direction. The chip regions CP and the element isolation regions STI at both ends of the scribe region 10 as shown in FIG. 22 are covered by conductive film PS1. The conductive film PS1 between the mark regions TR1a and TR2a is left as a boundary to distinguish between these mark regions.

The above step corresponds to the step described earlier referring to FIGS. 5 and 6. In other words, the pattern PT1a is an inspection pattern used to check whether or not the patterns of the select gate electrodes CG1 and CG2 formed simultaneously with the pattern PT1a are in the desired position with respect to the semiconductor substrate. The pattern PT2a is a pattern used to determine the position of the photo mask in the lithographic step subsequent to the above step.

Therefore, in a plan view, the pattern PT1a has a rectangular annular shape like the pattern PT1 shown in FIG. 5 and the pattern PT2a has a linear shape like the pattern PT2 shown in FIG. 5. The width of the pattern PT1a (PT2a) is the same as that of the pattern PT1 (PT2) and the size of the mark region TR1a (TR2a) is the same as that of the mark region TR1 (TR2). However, the mark regions TR1a and TR2a in the comparative example are structurally different from the mark regions TR1 and TR2.

More specifically, in the semiconductor device under the manufacturing process according to the embodiment shown in FIGS. 5 and 6, the inspection patterns PT1 and PT2 are trenches W1 and W2 as linear openings made by partially removing the laminated film including the conductive film PS1 and insulating films IO and CA in the mark regions TR1 and TR2. Therefore, most of the mark region TR1 (TR2) remains covered by the conductive film PS1, so in the mark region TR1 (TR2) the area of the trench W1 (W2) made by partial removal of the conductive film PS1 as the inspection pattern PT1 (PT2) is smaller than the area of the conductive film PS1 in a plan view.

On the other hand, in the comparative example shown in FIGS. 22 and 23, the inspection patterns PT1a and PT2a are linear patterns of the laminated film left by partially removing the laminated film including the conductive film PS1 and insulating films IO and CA in the mark regions TR1a and TR2a. Since the width of the pattern PT1a (PT2a) is very small as compared to one side of the mark region TR1a (TR2a), the area of the linear pattern PT1a (PT2a) extending in a direction in a plan view is very small as compared to the area of the mark region TR1a (TR2a) in a plan view.

In the mark region TR1a (TR2a), the area of the region in which the conductive film PS1 is removed is larger than the area of the conductive film PS1 of the inspection pattern PT1a (PT2a) in a plan view and most of the mark region TR1a (TR2a) is exposed from the conductive film PS1.

As explained above, while the patterns PT1 and PT2 are trenches W1 and W2 respectively in this embodiment, the patterns PT1a and PT2a are linear patterns of remaining film in the comparative example.

Next, the patterns PT0 and PT1a in the mark region TR1a (FIG. 22) are observed to check their positional relation to find whether or not there is misalignment in the positions of the select gate electrodes CG1 and CG2 formed simultaneously with the mark region TR1a (FIG. 23).

Next, the same steps as described earlier referring to FIGS. 7 to 10 are carried out. Specifically, after removal of the insulating film CA in the peripheral circuit region 1B (FIG. 23), a memory gate electrode MG1 (MG2) is formed on one side face of the select gate electrode CG1 (CG2) through the ONO film CS (FIG. 10). When the lithographic step described referring to FIG. 7 or FIG. 9 is carried out, the position of the photo mask is adjusted using the pattern PT2a as the alignment mark shown in FIG. 22.

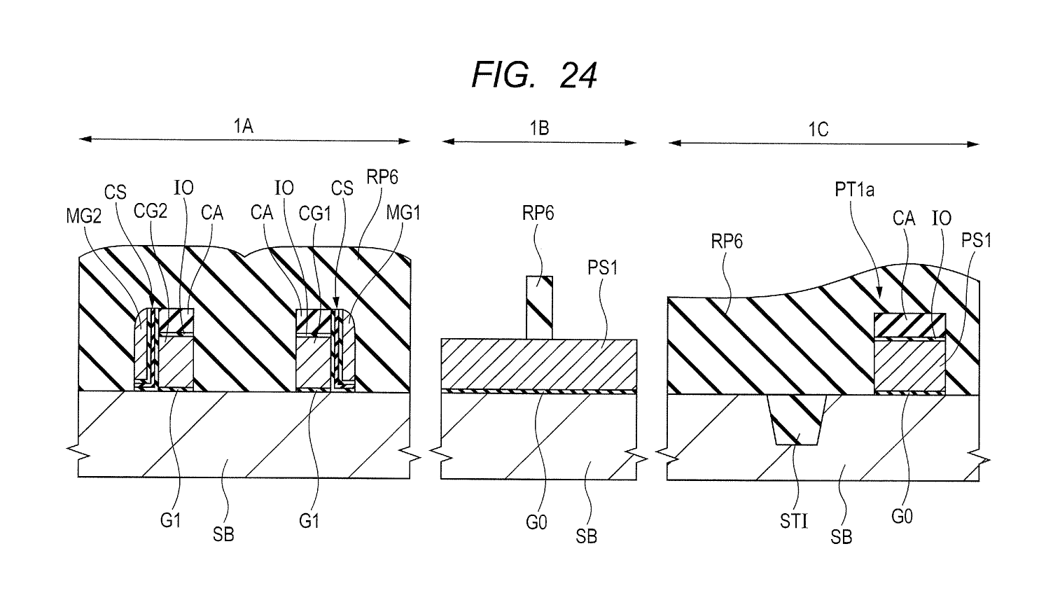

Next, as shown in FIG. 24, after n-type impurities are selectively doped into the conductive film PS1 in the peripheral circuit region 1B by ion implanting, a photoresist film RP6 is coated over the semiconductor substrate SB. Then, a portion of the conductive film PS1 in the peripheral circuit region 1B and the insulating film CA over a portion of the conductive film PS1 in the scribe region 1C are exposed from the photoresist film RP6 by exposure and development. In other words, the photoresist film RP6 covers the memory region 1A and partially covers the peripheral circuit region 1B and scribe region 1C. This step corresponds to the step described referring to FIG. 11.

In the cross section of the scribe region 1C shown in FIG. 24, the photoresist film RP1 does not expose the insulating film CA. It is in a region not shown in FIG. 24, namely a mark region other than the mark regions TR1a and TR2a shown in FIG. 22 that the photoresist film RP6 partially exposes the insulating film CA in the scribe region 1C. In the coated photoresist film RP6 in the mark region not shown in the figure, a rectangular annular opening in a plan view like the pattern PT1a in the mark region TR1a is made and the insulating film CA is exposed on the bottom of the opening.

As shown in FIGS. 22 to 24, the laminated film including the insulating films CA and IO and conductive film PS1 is removed over the main surface of the semiconductor substrate SB except the region in which the pattern PT1a is formed or the laminated film is left. In short, in the mark region TR1a (FIG. 22), the area of the pattern PT1a is far smaller than the area of the region in which the laminated film is removed.

Therefore, in the scribe region 1C in the comparative example, since the laminated film including the conductive film PS1 is removed by the step described referring to FIGS. 22 and 23, most of the main surface of the semiconductor substrate SB in the mark region TR1a is exposed. In this case, when the photoresist film RP6 (FIG. 24) is coated to cover the pattern PT1a of the laminated film in the mark region TR1a, in the coating step the fluid photoresist film RP6 flows into the large opening beside the laminated film of the pattern PT1a in the scribe region 1C and stays there.

The reason that the photoresist film RP6 is arranged mostly in the opening is that the pattern PT1a of the laminated film is sparsely formed without leaving the laminated film densely in a relatively large region such as the mark regions TR1a and TR2a and the photoresist film RP6 flows into the large recess in a plan view. Thus, just after the above coating step, due to its fluidity the photoresist film RP6 immediately above the pattern PT1a flows into the recess beside the pattern PT1a.

On the other hand, in the memory region 1A, a plurality of laminated films including the insulating films CA and IO and select gate electrode CG1 or CG2 are arranged adjacent to each other to form patterns densely. Therefore, the distance between patterns of such laminated film is not large and even if the photoresist film RP6 has fluidity, little photoresist flows into the recess between the patterns. Furthermore, in the peripheral circuit region 1B, the whole main surface of the semiconductor substrate SB is covered by conductive film PS1 and the conductive film PS1 has no opening. Therefore, there is no possibility that the photoresist film RP6 over the conductive film PS1 flows into an opening in the conductive film PS1.

In the scribe region 1C, after the above coating step, due to its fluidity the photoresist film RP6 flows beside the pattern PT1a, so the photoresist film RP6 immediately above the pattern PT1a formed by the step described referring to FIG. 24 is thinner than the photoresist film RP6 immediately above the laminated film including the insulating films CA and IO and select gate electrode CG1 in the memory region 1A. Similarly the photoresist film RP6 immediately above the pattern PT1a is thinner than the photoresist film RP6 immediately above the laminated film including the insulating films CA and IO and select gate electrode CG2 in the memory region 1A and thinner than the photoresist film RP6 immediately above the conductive film PS1 in the peripheral circuit region 1B.

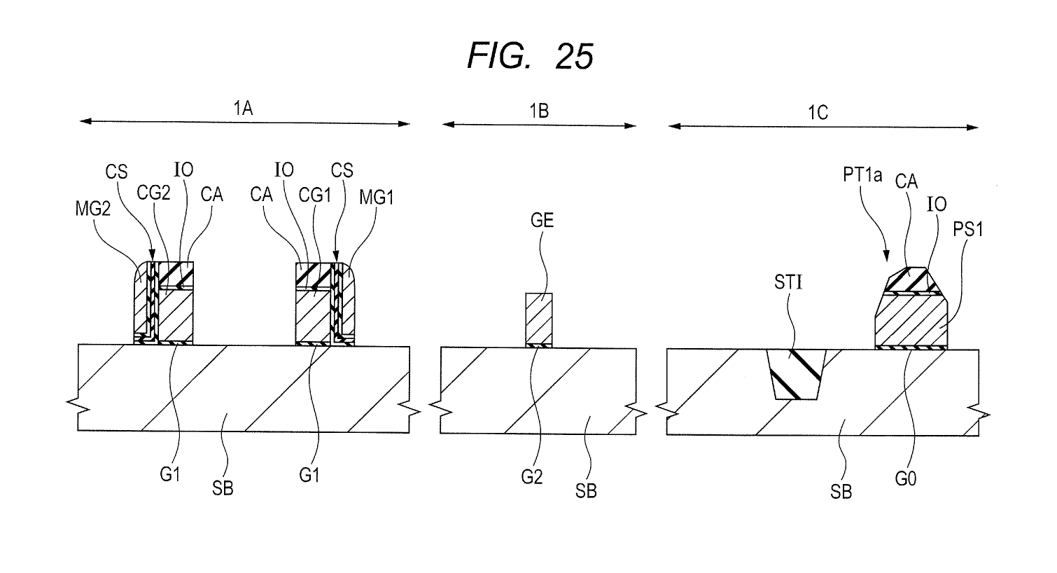

Next, as shown in FIG. 25, in the peripheral circuit region 1B, a low-voltage nMIS gate electrode GE of conductive film PS1 and a gate insulating film G2 of insulating film G0 are formed by partially removing the conductive film PS1 and the insulating film G0 by dry etching using the photoresist film RP6 as a mask. Also, in the above step, an inspection pattern as a trench which exposes a portion of the upper surface of the semiconductor substrate SB is formed by removing the conductive film PS1 in a given mark region (not shown) of the scribe region 1C. Then, the photoresist film RP6 over the semiconductor substrate SB is removed.

The inspection pattern formed here corresponds to the pattern PT3 for use in the inspection step to check the position of the gate electrode GE, which has been described referring to FIGS. 12 and 13. In this case, the inspection pattern is not a trench but a linear laminated film including the conductive film PS1 left over the semiconductor substrate SB, like the pattern PT1a shown in FIG. 22.

The scribe region 1C is covered by the photoresist film RP6 in the step described referring to FIG. 24 in order to prevent the film in the scribe region 1C from being removed by the etching step to form the gate electrode GE. However, as mentioned above, the thickness of the photoresist film RP6 formed by the step described referring to FIG. 24 is very thin immediately above the pattern PT1a in the scribe region 1C. If the above etching is performed in this condition, the photoresist film RP6 immediately above the pattern PT1a may be depleted to the extent that the pattern PT1a is exposed from the photoresist film RP6 and consequently the top of the pattern PT1a is etched.

If the photoresist film RP6 immediately above the pattern PT1a is removed during the etching step, the pattern PT1a might be etched until the pattern PT1a is completely removed. Also, if the pattern PT1a is partially removed, eventually the pattern PT1a might be peeled off the semiconductor substrate SB. Even if the pattern PT1a is not completely removed, an edge corner of the upper surface of the pattern PT1a might be chipped as shown in FIG. 25. Although FIG. 25 only shows a cross section of the inspection pattern PT1a shown in FIG. 22, the laminated film of the pattern PT2a as the alignment mark shown in FIG. 22 might also be partially removed because the photoresist film RP6 immediately above it is thin.

After that, the positions of the pattern PT0 (FIG. 22) and the inspection pattern are detected using an inspection optical instrument. By doing so, whether or not the gate electrode GE is in the desired position with respect to the semiconductor substrate SB under the gate electrode GE is checked.

As the subsequent steps, the steps described referring to FIGS. 14 to 21 are carried out to produce the semiconductor device in the comparative example. In this process, it is necessary to carryout the step of forming a semiconductor region with a desired impurity concentration selectively by ion implanting using the photoresist film as a mask, as shown in FIGS. 14 to 16 and FIG. 18 and when making contact holes CH (FIG. 21), it is necessary to prevent misalignment in the position of the photoresist film in order to form the photoresist film accurately.

In these lithographic steps, the pattern PT2a shown in FIG. 22 is used when adjusting the position of the photo mask in order to form a resist pattern of photoresist film with a prescribed shape for the select gate electrode CG1 and the like. When the pattern PT2a as an alignment mark is detected using an optical instrument, etc., the shape of the pattern PT2a can be detected by recognizing the corners of the pattern PT2a. This means that the corners of the pattern PT2a should be not missing but should be almost square.

As described referring to FIGS. 24 and 25, however, the pattern PT2a (FIG. 22) is sparsely formed in the mark region TR2a (FIG. 22) like the pattern PT1a. For this reason, if a portion of the pattern PT2a, such as a corner of it, is removed during the etching step described referring to FIGS. 24 and 25 and the sectional shape of the pattern PT2a is not rectangular but distorted, it would be difficult to detect the alignment mark as the pattern PT2a accurately in the above lithographic process. If the pattern PT2a is completely missing or peeled, it would be impossible to detect the alignment mark.

Furthermore, after the step described referring to FIG. 25, in an attempt to inspect for misalignment between the pattern PT1a and the inspection pattern, if the pattern PT1a is partially missing as shown in FIG. 25, it would be impossible to compare the positions of the patterns accurately in the inspection.

For this reason, in the semiconductor device manufacturing method according to the comparative example, since it is difficult to form the photoresist film accurately after the step described referring to FIG. 25, there arises the problem that a patterning step using the photolithographic technique or ion implanting step cannot be performed accurately. Therefore, if the semiconductor device manufacturing process according to the comparative example is adopted, it is difficult to make a pattern with a desired shape or implant ions in the desired position, leading to deterioration in the reliability of the semiconductor device.

In addition to the problem of photolithographic technological accuracy, if the pattern PT1a or PT2a in the mark region TR1a or TR2a is partially or completely missing or peeled, the amount of etching residues over the semiconductor substrate SB might increase, resulting in deterioration in the reliability of the semiconductor device.

The above problem occurs when a film is processed several times and an inspection pattern is sparsely formed in a relatively large region in one of such processing steps before the final processing step. A similar problem may occur if a plurality of films with the same height is formed in different steps and several processing steps are carried out on the films.

One possible solution to the above problem is to increase the thickness of the photoresist film RP6 formed in the step described referring to FIG. 24 to prevent the pattern PT1a, etc. from being exposed in the etching step described referring to FIG. 25 even if the photoresist film RP6 flows. However, if the thickness of the photoresist film RP6 shown in FIG. 24 is increased, a photoresist film with a small width, such as the photoresist film RP6 made to form the low-voltage nMIS gate electrode GE (FIG. 25) with a small gate length in the peripheral circuit region 1B by etching, might collapse. Therefore, to increase the thickness of the photoresist film RP6 is not a good solution since it entails the risk that etching cannot be made properly.

In this embodiment, in order to prevent the corner of the pattern required to detect the inspection pattern from being chipped, trenches made by removal of the film are used as the inspection pattern and other character patterns in the mark regions. As shown in FIG. 11, the pattern PT1 is a linear trench W1 with a very small width as compared to one side of the scribe region 1C. For this reason, the amount of the photoresist film RP2 immediately above the laminated film including the insulating films CA and IO and conductive film PS1 over the scribe region 1C which flows into and over the recess beside the laminated film, namely trench W1, is small.

This is because the laminated film including the insulating films CA and IO and conductive film PS1 is densely formed in each mark region and there is any recess as an opening in the laminated film that is larger than the laminated film in each mark region in a plan view.

Therefore, a photoresist film RP2 with a thickness required not to expose the laminated film can be made immediately above the laminated film in the scribe region 1C during the etching step described referring to FIGS. 12 and 13. The same can be said for the mark region TR2 in which the pattern PT2 as the alignment mark shown in FIG. 5 is formed.

Also, the character pattern CR1 shown in FIG. 5 is also made of narrow trenches W4, which prevents the photoresist film RP2 immediately above the surrounding laminated film from flowing into and over the trenches W4. The same can be said for the trench W3 made as a boundary line.

In other words, in this embodiment, patterns of the laminated film are not sparsely formed in relatively large regions such as the mark regions TR1 and TR2 shown in FIG. 5 and the recesses or openings in the laminated film are small, so there is no possibility that the top of the inspection mark of the laminated film is partially missing.

As explained so far, according to this embodiment, an inspection pattern is made of a trench (trenches), thereby eliminating the possibility that the corner of the pattern for inspection is missing and ensuring accuracy in the detection of the pattern. Consequently even when the same film is processed several times, a mask pattern of photoresist film with the desired shape can be formed so that patterning based on the photolithographic technique or ion implanting can be performed accurately and the reliability of the semiconductor device can be improved.

The invention made by the present inventors has been so far explained concretely in reference to the preferred embodiment thereof. However, the invention is not limited thereto and it is obvious that these details may be modified in various ways without departing from the spirit and scope thereof.

What is claimed is:

1. A semiconductor device manufacturing method comprising the steps of:
(a1) providing a semiconductor substrate;
(b1) forming a first film to cover a first region and a second region of a main surface of the semiconductor substrate;
(c1) processing the first film in the first region to form a first pattern as an opening in the first film;
(d1) after the step (c1) above, forming a photoresist film to cover the first region and cover a portion of the first film in the second region;
(e1) performing etching using the photoresist film as a mask to process the first film in the second region; and
(f1) after the step (e1) above, inspecting the first pattern,
wherein a portion of the first region which is covered by the first film has a larger area than the first pattern in a plan view.

2. The semiconductor device manufacturing method according to claim 1,
wherein the first pattern is made of one or plural trenches extending in a direction.

3. The semiconductor device manufacturing method according to claim 1,
wherein in the step (f1), a photo mask position is adjusted by inspecting the first pattern in a lithographic process.

4. The semiconductor device manufacturing method according to claim 1, further comprising the step of:
(a2) before the step (f1), forming a third pattern made of a second film embedded in the main surface of the semiconductor substrate;
wherein in the step (c1), the first film covering a third region of the main surface of the semiconductor substrate is processed to form a second pattern, and
wherein in the step (f1), a position of the second pattern with respect to the semiconductor substrate is inspected by observing the third pattern and the first pattern.

5. The semiconductor device manufacturing method according to claim 1,
wherein in the step (f1), the first pattern is inspected by detecting a corner of the first film immediately above a boundary between the first film and the first pattern.

6. The semiconductor device manufacturing method according to claim 5,
wherein the first pattern is a recess in a region surrounded by the corner.

7. The semiconductor device manufacturing method according to claim 4,
wherein the second region and the third region are a region for formation of a peripheral circuit and a region for formation of a nonvolatile memory respectively;
wherein in the step (c1), a select gate electrode made of the second pattern is formed over the semiconductor substrate through a first gate insulating film;
the method further comprising the step of:
(c2) after the step (c1), forming a memory gate electrode adjacent to one sidewall of the select gate electrode and the semiconductor substrate through an insulating film including a charge storage layer,
wherein in the step (e1), a gate electrode made of the first film in the second region is formed over the semiconductor substrate through a second gate insulating film by processing the first film in the second region.

8. The semiconductor device manufacturing method according to claim 1,
wherein the first region is a scribe region.
